(19) United States
(12) Patent Application Publication
(10) Pub. No.: US 2017/0205661 A1
(43) Pub. Date: Jul. 20, 2017

(54) DISPLAY DEVICE AND MANUFACTURING METHOD THEREOF

(71) Applicant: Samsung Display Co., Ltd., Yongin-si, (KR)

(72) Inventors: Choi Sang PARK, Suwon-si (KR); Seong Gyu KWON, Suwon-si (KR); Sang Il KIM, Yongin-si (KR); Tae Woo LIM, Yongin-si (KR)

(21) Appl. No.: 15/235,844

(22) Filed: Aug. 12, 2016

(30) Foreign Application Priority Data
Jan. 14, 2016 (KR) 10-2016-0004621

(51) Int. Cl. G02F 1/1333; G02F 1/1339; G02F 1/1343; H01L 27/12; G02F 1/1368

(52) U.S. Cl. CPC G02F 1/133377; H01L 27/124; G02F 1/1368; G02F 1/13439; G02F 1/1339

(57) ABSTRACT

An exemplary embodiment provides a display device and a manufacturing method thereof. A display device according to the exemplary embodiment includes: a substrate; a thin film transistor disposed on the substrate; a first electrode connected to the thin film transistor; a roof layer disposed on the first electrode and spaced apart from the first electrode by interposing a microcavity therebetween; a liquid crystal layer positioned inside the microcavity; an encapsulation layer positioned on the roof layer; and a barrier layer covering an upper surface and a lateral surface of the encapsulation layer, wherein a lateral surface of the barrier layer includes a thermal distortion portion.

### RELATED APPLICATIONS

This application claims priority to and the benefit of Korean Patent Application No. 10-2016-0004621 filed in the Korean Intellectual Property Office on Jan. 14, 2016, the entire contents of which are incorporated herein by reference.

### BACKGROUND

1. Field

The described technology relates generally to a display device and a manufacturing method thereof.

2. Description of the Related Art

One of the currently most widely used flat panel displays, a liquid crystal display (LCD), includes two sheets of display panels formed with field generating electrodes and a liquid crystal layer interposed therebetween. The LCD displays an image by applying a voltage to the field generating electrodes to generate an electric field in a liquid crystal layer, determining alignment directions of liquid crystal molecules of the liquid crystal layer by the generated field, and controlling polarization of incident light.

The two sheets of display panels included in the LCD may be a thin film transistor array panel and an opposed display panel. In the thin film transistor array panel, a gate line for transmitting a gate signal and a data line for transmitting a data signal are formed to cross each other, and a thin film transistor connected to the gate and data lines, as well as a pixel electrode connected to the thin film transistor, may be formed. A light blocking member, a color filter, a common electrode, and the like may be formed in the opposed display panel. In some embodiments, the light blocking member, the color filter, and the common electrode may be formed in the thin film transistor array panel.

However, in conventional LCDs, since two sheets of substrates are required and components are respectively formed on the two sheets of substrates, there is a problem in that the display device not only becomes heavy, thick, and costly, but also requires a longer processing time.

The above information disclosed in this Background section is only for enhancement of understanding of the background of the invention, and therefore it may contain information that does not form the prior art already known in this country to a person of ordinary skill in the art.

### SUMMARY

The inventive concept has been made in an effort to provide a display device and a manufacturing method thereof that are capable of reducing thickness, width, cost, and processing time by manufacturing the display device using one substrate.

As such, when the display device is manufactured using one substrate, an encapsulation layer for encapsulating a liquid crystal layer may be formed. The encapsulation layer includes an organic material. Thus, there is a problem that oxygen and moisture permeate through the encapsulation layer from the outside, and characteristics of a device are deteriorated.

Accordingly, the exemplary embodiment has been made in an effort to provide a display device and a manufacturing method thereof that prevent oxygen and moisture from permeating through the encapsulation layer.

An exemplary embodiment provides a display device, including: a substrate; a thin film transistor disposed on the substrate; a first electrode connected to the thin film transistor; a roof layer disposed on the first electrode and spaced apart from the first electrode by interposing a microcavity therebetween; a liquid crystal layer positioned inside the microcavity; an encapsulation layer positioned on the roof layer; and a barrier layer covering an upper surface and a lateral surface of the encapsulation layer, wherein a lateral surface of the barrier layer includes a thermal distortion portion.

The encapsulation layer may include an organic material, and the barrier layer may include an inorganic material.

The barrier layer may include silicon nitride.

A lateral surface of the encapsulation layer may include a thermal distortion portion.

An angle between the lateral surface of the encapsulation layer and the substrate may be equal to or greater than about 80°.

The substrate may include a display area and a peripheral area, and the thermal distortion portion of the barrier layer may be disposed on either a boundary between the display area and the peripheral area, or a portion of the peripheral area adjacent the boundary.

The barrier layer may include a first barrier layer and a second barrier layer disposed on the first barrier layer.

The first barrier layer may include an inorganic material, and the second barrier layer may include an organic material.

The barrier layer may further include a third barrier layer disposed on the second barrier layer.

The first barrier layer and the third barrier layer may include an inorganic material, and the second barrier layer may include an organic material.

The exemplary embodiment may further include a ground pattern disposed on the substrate, and the ground pattern may be connected to the barrier layer.

The barrier layer may include a transparent conductive material.

A plan shape of the ground pattern may be a rod shape or a dot shape.

The substrate may include a display area and a peripheral area, and the ground pattern may be disposed on the peripheral area or a boundary between the display area and the peripheral area.

An exemplary embodiment provides a display device, including: a substrate; a ground pattern disposed on the substrate; a thin film transistor disposed on the substrate; a first electrode connected to the thin film transistor; a roof layer disposed on the first electrode and spaced apart from the first electrode by interposing a microcavity therebetween; a liquid crystal layer positioned inside the microcavity; an encapsulation layer positioned on the roof layer; and a barrier layer covering an upper surface and a lateral surface of the encapsulation layer and connected to the ground pattern.

The barrier layer may include a transparent conductive material.

An exemplary embodiment provides a manufacturing method of a display device, including: forming a thin film transistor on a display area of a substrate including the display area, a peripheral area, and an extra area; forming a first electrode to be connected to the thin film transistor; forming a sacrificial layer on the first electrode; forming a roof layer on the sacrificial layer; forming a microcavity between the first electrode and the roof layer by removing the sacrificial layer; forming an encapsulation layer on the roof layer; removing a portion of the encapsulation layer disposed on a boundary between the display area and the peripheral area of the substrate to form a trench; forming a barrier layer covering an upper surface and a lateral surface of the encapsulation layer; cutting a portion of the barrier layer disposed in the trench; cutting the boundary between the display area and the peripheral area; and removing a portion of the barrier layer disposed on the peripheral area and the extra area of the substrate.

Cutting a portion of the barrier layer disposed in the trench may include irradiating, with a laser, a portion of the barrier layer disposed on the boundary between the display area and the peripheral area of the substrate.

Removing a portion of the encapsulation layer may include irradiating, with a laser, a portion of the encapsulation layer disposed on the boundary between the display area and the peripheral area of the substrate.

The encapsulation layer may include an organic material, and the barrier layer may include an inorganic material.

The display device and the manufacturing method thereof according to the current exemplary embodiment as described above have the following effects.

According to the current exemplary embodiment, since the display device is manufactured using one substrate, the weight, thickness, cost, and processing time thereof can be reduced.

In addition, a barrier layer is formed to cover an upper surface and lateral surfaces of the encapsulation layer, thereby preventing permeation of oxygen and moisture.

Further, the barrier layer is connected to a ground pattern, thereby dispersing static electricity.

### BRIEF DESCRIPTION OF THE DRAWINGS

FIG. 1 is a plan view of a display device according to an exemplary embodiment.

FIG. 2 is a partial plan view of a display device according to an exemplary embodiment.

FIG. 3 is a cross-sectional view of a display device according to an exemplary embodiment taken along the line III-III of FIG. 2.

FIG. 4 is a cross-sectional view of a display device according to an exemplary embodiment taken along the line IV-IV of FIG. 2.

FIGS. 5, 6, 7, 8, 9, 10, 11, 12, 13, 14, 15, 16, 17, 18, 19, 20, 21, and 22 are process cross-sectional views of a manufacturing method of a display device according to an exemplary embodiment.

FIG. 23 and FIG. 24 are cross-sectional views of a display device according to an exemplary embodiment of the present invention.

FIG. 25 is a plan view of a display device according to an exemplary embodiment.

FIG. 26 is a partial plan view of a display device according to an exemplary embodiment.

FIG. 27 is a cross-sectional view of a display device according to an exemplary embodiment taken along the line XXVII-XXVII of FIG. 26.

FIG. 28 is a plan view of a display device according to an exemplary embodiment.

### DETAILED DESCRIPTION OF THE EMBODIMENTS

The exemplary embodiments will be described more fully hereinafter with reference to the accompanying drawings, in which exemplary embodiments are shown. As those skilled in the art would realize, the described embodiments may be modified in various different ways, all without departing from the spirit or scope of the exemplary embodiment.

Parts that are irrelevant to the description will be omitted to clearly describe the inventive concept, and like reference numerals designate like elements throughout the specification.

Further, in the drawings, the size and thickness of each element are arbitrarily illustrated for ease of description, and the inventive concept is not necessarily limited to those illustrated in the drawings.

In the drawings, the thickness of layers, films, panels, regions, etc., are exaggerated for clarity. It will be understood that when an element such as a layer, film, region, or substrate is referred to as being “on” another element, it can be directly on the other element or intervening elements may also be present.

In addition, unless explicitly described to the contrary, the word “comprise” and variations such as “comprises” or “comprising” will be understood to imply the inclusion of stated elements but not the exclusion of any other elements. Further, “on”, “over”, “under”, or “beneath” does not only mean directly on or directly under an element based on a gravity direction.

In addition, “in a plan view” means viewing from above the element, and “in a cross-sectional view” means viewing a cross-section from the side.

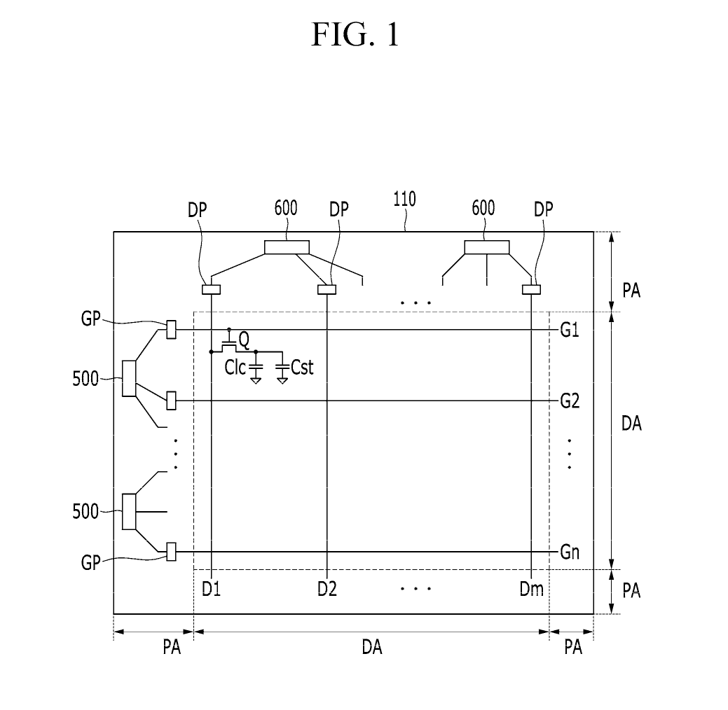

Referring first to FIG. 1, a display device according to an exemplary embodiment will be described.

FIG. 1 is a plan view of a display device according to an exemplary embodiment.

The display device according to the exemplary embodiment includes a substrate 110 that is made of a material such as glass or plastic.

The substrate 110 is divided into a display area DA and a peripheral area PA. The display area DA is positioned in a center part of the substrate 110, and the peripheral area PA surrounds an edge of the display area DA. The display area DA is an area on which an image is displayed, and drivers for transmitting driving signals are disposed in the peripheral area PA to allow the image to be displayed on the display area DA.

In the display area DA, a plurality of gate lines G1 to Gn are formed to be parallel to each other, and a plurality of data lines D1 to Dm are formed to be parallel to each other. The plurality of gate lines G1 to Gn and the plurality of data lines D1 to Dm are insulated from each other, and cross each other to define a plurality of pixels.

In each pixel, a thin film transistor Q, an LC capacitor Clc, and a storage capacitor Cst are formed. A control terminal of the thin film transistor Q is connected to any one of the plurality of gate lines G1 to Gn, an input terminal thereof is connected to any one of the plurality of data lines D1 to Dm, and an output terminal thereof is connected to one terminal of the LC capacitor Clc and one terminal of the storage capacitor Cst. A common voltage may be applied to the other terminal of the LC capacitor Clc, and a reference voltage may be applied to the other terminal of the storage capacitor Cst.

The gate lines G1 to Gn and the data lines D1 to Dm extend even to the peripheral area PA. Gate pad portions GP connected to the gate lines G1 to Gn and data pad portions DP connected to the data lines D1 to Dm are positioned in the peripheral area PA. The gate pad portions GP may be connected to a gate driver 500, and receive a gate signal from the gate driver 500 to transmit the gate signal to the gate lines G1 to Gn. The data pad portions DP may be connected to a data driver 600, and receive a data signal from the data driver 600 to transmit the data signal to the data lines D1 to Dm.

In FIG. 1, the gate pad portions GP are illustrated to be positioned at a left edge of the display area DA, but the exemplary embodiment is not limited thereto, and the position of the gate pad portions GP may be variously changed. For example, the gate pad portions GP may be positioned at opposite lateral edges of the display area DA.

In FIG. 1, the data pad portions DP are illustrated to be positioned at an upper edge of the display area DA, but the exemplary embodiment is not limited thereto, and the position of the data pad portions DP may be variously changed. For example, the data pad portion DP may be positioned at both lateral edges of the display area DA.

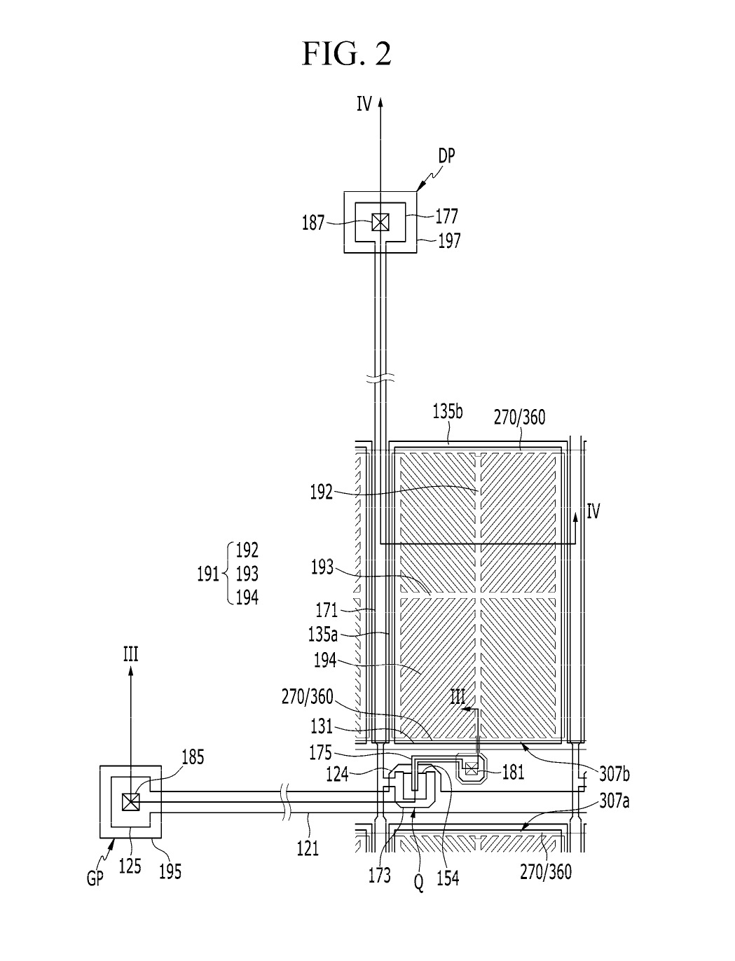

Structures of one pixel and pad portions of a display device according to an exemplary embodiment will now be described with reference to FIGS. 2 to 4.

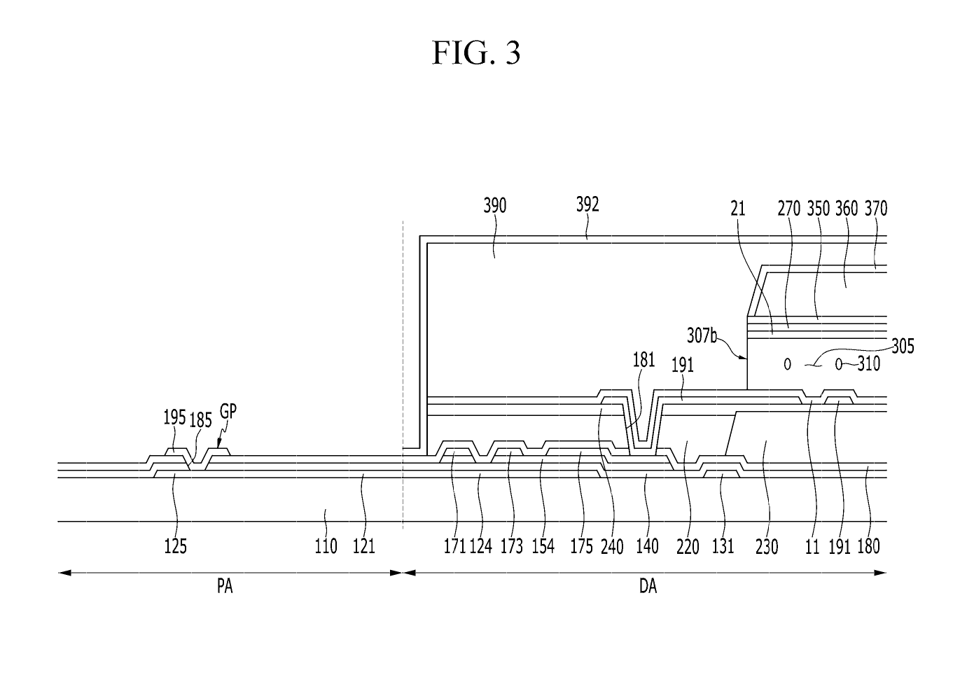

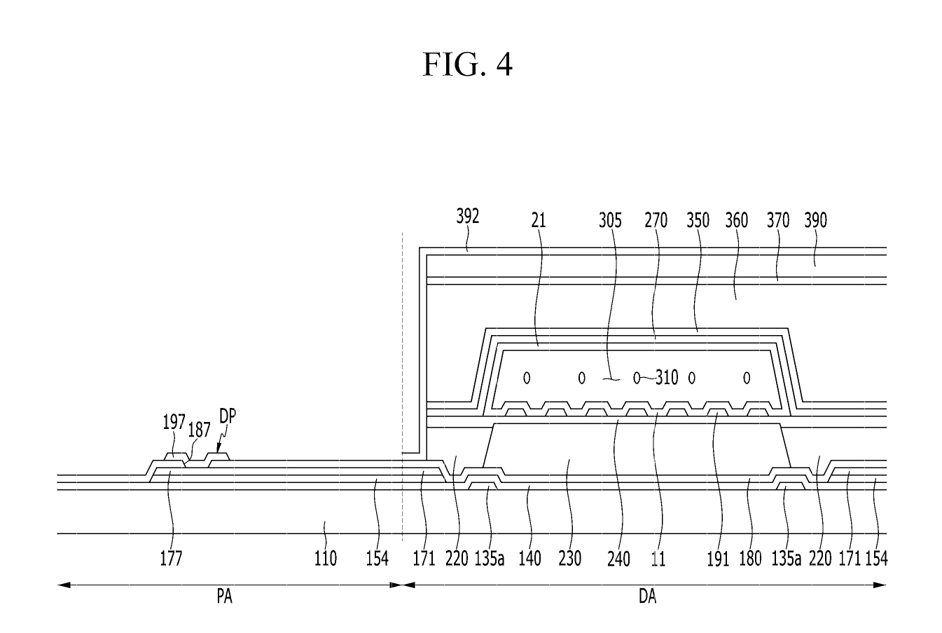

FIG. 2 is a partial plan view of a display device according to an exemplary embodiment, FIG. 3 is a cross-sectional view of the display device according to the exemplary embodiment taken along the line III-III of FIG. 2, and FIG. 4 is a cross-sectional view of the display device according to the exemplary embodiment taken along the line IV-IV of FIG. 2.

Referring to FIG. 2 to FIG. 4, a gate line 121, a gate electrode 124 protruding from the gate line 121, and a gate pad 125 connected to the gate line are disposed on the substrate 110.

The gate line 121 extends in a first direction, and transmits a gate signal. For example, the gate line 121 may extend in an approximately horizontal direction. In a plan view, the gate electrode 124 protrudes upward of the gate line 121. However, the exemplary embodiment is not limited thereto, and a protruding shape of the gate electrode 124 may be variously modified. Alternatively, the gate electrode 124 may not protrude from the gate line 121, and may be disposed on the gate line 121. The gate line 121 and the gate electrode 124 are disposed in the display area DA, and the gate line 121 is extended to the peripheral area PA.

The gate pad 125 extends from an end portion of the gate line 121. The end portion of the gate line 121 is disposed in the peripheral area PA, and the gate pad 125 is positioned in the peripheral area PA. The gate pad 125 may have a wider width than of the gate line 121. The gate pad 125 may be made of the same material as the gate line 121 and the gate electrode 124, and may be disposed as the same layer.

A reference voltage line 131 and storage electrodes 135a and 135b protruding from the reference voltage line 131 may be further formed on the substrate 110.

The reference voltage line 131 extends in a direction parallel to the gate line 121, and is spaced apart from the gate line 121. A constant voltage may be applied to the reference voltage line 131. The storage electrodes 135a and 135b include a pair of first storage electrodes 135a extending substantially perpendicular to the reference voltage line 131, and a second storage electrode 135b connecting the pair of first storage electrodes 135a. The reference voltage line 131 and the storage electrodes 135a and 135b may surround a pixel electrode 191 to be described below.

A gate insulating layer 140 is disposed on the gate line 121, the gate electrode 124, the gate pad 125, the reference voltage line 131, and the storage electrodes 135a and 135b. The gate insulating layer 140 may be made of an inorganic insulating material such as a silicon nitride (SiNx) or a silicon oxide (SiOx). In addition, the gate insulating layer 140 may consist of a single layer or multiple layers.

A semiconductor 154 is disposed on the gate insulating layer 140. The semiconductor 154 may be disposed on the gate electrode 124. The semiconductor 154 may be made of amorphous silicon, polycrystalline silicon, or a metal oxide.

An ohmic contact member (not shown) may be disposed on the semiconductor 154. The ohmic contact member may be made of a silicide or a material such as n+ hydrogenated amorphous silicon in which an n-type impurity is doped at a high concentration. When the semiconductor 154 is made of a metal oxide, the ohmic contact member may be omitted.

A data line 171, a source electrode 173, a drain electrode 175, and a data pad 177 are disposed on the semiconductor 154 and the gate insulating layer 140.

The data line 171 transmits a data signal and extends in a second direction to cross the gate line 121 and the reference voltage line 131. For example, the data line 171 may extend in an approximately vertical direction. In a cross-sectional view, the source electrode 173 protrudes above the gate electrode 124 from the data line 171, and in a plan view, the source electrode 173 may be bent in a U-shape. The drain electrode 175 includes one wide end portion and one rod-shaped end portion. The wide end portion of the drain electrode 175 overlaps the pixel electrode 191. The rod-shaped end portion of the drain electrode 175 is partially surrounded by the source electrode 173. However, the exemplary embodiment is not limited thereto, and shapes of the source electrode 173 and the drain electrode 175 may be variously modified. The data line 171, the source electrode 173, and the drain electrode 175 are disposed in the display area DA, and the data line 171 is extended to the peripheral area PA.

The data pad 177 is connected to the data line 171. The data pad 177 is extended from an end portion of the data line 171, and both the data pad 177 and end portion of the data line 171 are positioned in the peripheral area PA. The data pad 177 may have a wider width than the data line 171. The data pad 177 may be made of the same material as and disposed on the same layer as the data line 171, the source electrode 173, and the drain electrode 175.

The gate electrode 124, the source electrode 173, and the drain electrode 175 form one thin film transistor (TFT) Q along with the semiconductor 154. In this case, a channel of the thin film transistor Q is formed in the semiconductor 154 between the source electrode 173 and the drain electrode 175.

A passivation layer 180 is disposed on the data line 171, the source electrode 173, the drain electrode 175, an exposed portion of the semiconductor 154, and the data pad 177. The passivation layer 180 may be made of an organic insulating material or an inorganic insulating material, and may consist of a single layer or multiple layers.

On the passivation layer 180, color filters 230 are disposed inside each pixel.

Each color filter 230 may display one of three primary colors such as red, green, and blue. The color filter 230 may not be limited to displaying the three primary colors such as red, green, and blue, but may display cyan, magenta, yellow, and white-based colors.

A light blocking member 220 is disposed between adjacent color filters 230. The light blocking member 220 may be positioned at an edge of the pixel, and may overlap the gate line 121, the data line 171, and the thin film transistor Q to prevent light leakage. However, the exemplary embodiment is not limited thereto, and the light blocking member 220 may overlap the gate line 121 and the thin film transistor Q, but not the data line 171. In this case, in order to prevent light leakage, the adjacent color filters 230 may overlap each other in a portion where the light blocking member 220 overlaps the data line 171. The color filter 230 and the light blocking member 220 may overlap each other in some regions.

A first insulating layer 240 may be further disposed on the color filter 230 and the light blocking member 220. The first insulating layer 240 may be made of an organic insulating material, and may serve to planarize upper surfaces of the color filter 230 and the light blocking member 220. The first insulating layer 240 may be a dual layer that includes a layer made of an organic insulating material and a layer made of an inorganic insulating material. Alternatively, the first insulating layer 240 may be omitted, as the case may be.

The first insulating layer 240, the light blocking member 220, and the passivation layer 180 have a first contact hole 181 overlapping at least a portion of the drain electrode 175. The first contact hole 181 may overlap the wide end portion of the drain electrode 175. In addition, the passivation layer 180 and the gate insulating layer 140 have a second contact hole 185 overlapping at least a portion of the gate pad 125, and a third contact hole 187 overlapping at least a portion of the data pad 177.

The pixel electrode 191 is disposed on the first insulating layer 240. The pixel electrode 191 may be made of a transparent metal oxide such as an indium tin oxide (ITO) or an indium zinc oxide (IZO). The pixel electrode 191 is connected to the drain electrode 175 through the first contact hole 181. Accordingly, when the thin film transistor Q is turned on, a data voltage is applied to the drain electrode 175 through the pixel electrode 191.

The pixel electrode 191 is generally quadrangular. The pixel electrode 191 includes a horizontal stem portion 193, a vertical stem portion 192, and a minute branch portion 194 extending from the horizontal and vertical stem portions 193 and 192. The pixel electrode 191 is divided into four subregions by the horizontal stem portion 193 and the vertical stem portion 192. The minute branch portion 194 obliquely extends from the horizontal stem portion 193 and the vertical stem portion 192, and may form an angle of about 45° or about 135° with an extending direction of the gate line 121 or the horizontal stem portion 193. In addition, extending directions of the minute branch portions 194 of the two adjacent subregions may be perpendicular to each other.

In the exemplary embodiment, the pixel electrode 191 may further include an outer stem portion that surrounds an outer edge of the pixel.

In addition, a gate contact assistant 195 and a data contact assistant 197 are positioned on the peripheral area PA of the substrate 110. The gate contact assistant 195 and the data contact assistant 197 may be disposed on the passivation layer 180.

The gate contact assistant 195 is connected to the gate pad 125 through the second contact hole 185. The gate contact assistant 195 may be made of the same material as and disposed on the same layer as the pixel electrode 191. The gate pad 125 and the gate contact assistant 195 are laminated to form a gate pad portion GP.

The data contact assistant 197 is connected to the data pad 177 through the third contact hole 187. The data contact assistant 197 may be made of the same material as and disposed on the same layer as the pixel electrode 191. The data pad 177 and the data contact assistant 197 are laminated to form a data pad portion DP.

The pixel electrode 191 may be disposed in the display area DA, and the gate contact assistant 195 and the data contact assistant 197 may be disposed in the peripheral area PA.

The layout of the pixel, the structure of the thin film transistor, and the shape of the pixel electrode described above are merely examples, and the exemplary embodiment is not limited thereto and may be variously modified. For example, one pixel may include a plurality of subpixels to which different voltages are respectively applied. For this purpose, a plurality of thin film transistors may also be formed in one pixel.

A common electrode 270 is disposed on the pixel electrode 191 to be spaced apart from the pixel electrode 191 by a predetermined distance. A microcavity 305 is disposed between the pixel electrode 191 and the common electrode 270. That is, the microcavity 305 is surrounded by the pixel electrode 191 and the common electrode 270. The common electrode 270 may extend in a row direction. The common electrode 270 covers an upper surface of the microcavity 305 and a portion of a lateral surface thereof. A size of the microcavity 305 may be variously modified depending on a size and resolution of the display device.

However, the exemplary embodiment is not limited thereto. For example, the common electrode 270 may be disposed on the pixel electrode 191 by a predetermined distance, with an insulating layer disposed between the common electrode 270 and the pixel electrode 191, and the microcavity 305 disposed on the common electrode 270.

It is illustrated that a plurality of microcavities 305 are disposed on the substrate 110 and that one microcavity 305 corresponds to one pixel. However, the exemplary embodiment is not limited thereto, so the microcavity 305 may correspond to a plurality of pixels, or the microcavity 305 may correspond to some of the pixels. When one pixel consists of two subpixels, the microcavity 305 may correspond to one subpixel. Alternatively, the microcavity 305 may correspond to two subpixels that neighbor each other.

The common electrode 270 may be made of a transparent metal oxide such as an indium tin oxide (ITO) or an indium zinc oxide (IZO). A constant voltage may be applied to the common electrode 270, and an electric field may be generated between the pixel electrode 191 and the common electrode 270.

Alignment layers 11 and 21 are formed on the pixel electrode 191 and under the common electrode 270.

The alignment layers 11 and 21 include a first alignment layer 11 and a second alignment layer 21. The first alignment layer 11 and the second alignment layer 21 may be vertical alignment layers, and may be made of an aligning material such as polyamic acid, polysiloxane, or polyimide. The first and second alignment layers 11 and 21 may be connected at a side wall of an edge of the microcavity 305.

The first alignment layer 11 is disposed on the pixel electrode 191. The first alignment layer 11 may also be disposed directly on at least some of the first insulating layer 240 that is not covered by the pixel electrode 191.

The second alignment layer 21 is disposed under the common electrode 270 to face the first alignment layer 11.

A liquid crystal layer including liquid crystal (LC) molecules 310 is disposed inside the microcavity 305 that is positioned between the pixel electrode 191 and the common electrode 270. The LC molecules 310 may have negative dielectric anisotropy, and may be disposed perpendicularly to the substrate 110 when no electric field is present. That is, vertical alignment may be achieved. However, the exemplary embodiment is not limited thereto, and horizontal alignment may be achieved.

The pixel electrode 191 to which the data voltage is applied generates an electric field along with the common electrode 270, thereby determining alignment directions of the LC molecules 310 disposed inside the microcavity 305 between the two electrodes 191 and 270. As such, luminance of light transmitted through the liquid crystal layer varies depending on the determined alignment directions of the LC molecules 310.

A second insulating layer 350 may be further formed on the common electrode 270. The second insulating layer 350 may be made of an inorganic insulating material such as a silicon nitride (SiNx) or a silicon oxide (SiOx), or may be omitted, as the case may be.

A roof layer 360 is formed on the second insulating layer 350. The roof layer 360 may be made of an organic material or an inorganic material. In addition, the roof layer 360 may consist of a single layer or multiple layers. The roof layer 360 may extend in a row direction. The roof layer 360 covers an upper surface of the microcavity 305 and a portion of a lateral surface thereof. The roof layer 360 may be hardened by a curing process to maintain a shape of the microcavity 305. The roof layer 360 is formed to be spaced apart from the pixel electrode 191 while interposing the microcavity 305 therebetween.

In the drawings, the color filter 230 is illustrated such that it is positioned under the microcavity 305, but the exemplary embodiment is not limited thereto. The position of the color filter 230 may be changed. For example, the roof layer 360 may be made of a color filter material, and in this case, the color filter 230 may be positioned on the microcavity 305.

The common electrode 270 and the roof layer 360 do not cover a portion of the lateral surface of the edge of the microcavity 305, and parts of the microcavity 305 which are not covered by the common electrode 270 and the roof layer 360 are called injection holes 307a and 307b. The injection holes 307a and 307b include a first injection hole 307a that exposes a lateral surface of a first edge of the microcavity 305, and a second injection hole 307b that exposes a lateral surface of a second edge of the microcavity 305. The first edge and the second edge face each other, and for example, in a plan view, the first edge may be an upper edge of the microcavity 305 and the second edge may be a lower edge of the microcavity 305. In a manufacturing process of the display device, since the microcavity 305 is exposed by the injection holes 307a and 307b, an aligning agent or an LC material may be injected into the microcavity 305 via the injection holes 307a and 307b.

A third insulating layer 370 may be further formed on the roof layer 360. The third insulating layer 370 may be made of an inorganic insulating material such as a silicon nitride (SiNx) or a silicon oxide (SiOx). The third insulating layer 370 may be formed to cover an upper surface of the roof layer 360 and/or a lateral surface thereof. The third insulating layer 370 may serve to protect the roof layer 360 that is made of an organic material, and may be omitted, as the case may be.

The third insulating layer 370 may have substantially the same plan shape as the roof layer 360. The roof layer 360 may consist of multiple layers, and in this case, the third insulating layer 370 may be one of layers that constitute the roof layer 360.

An encapsulation layer 390 is formed on the third insulating layer 370. The encapsulation layer 390 may cover the injection holes 307a and 307b. That is, the encapsulation layer 390 may encapsulate the microcavity 305 such that the LC molecules 310 disposed inside the microcavity 305 do not leak to the outside.

The encapsulation layer 390 may be made of an organic insulating material. The encapsulation layer 390 is preferably made of a material that does not react with the LC molecules 310, since it contacts the LC molecules 310. For example, the encapsulation layer 390 may be made of perylene or the like.

The encapsulation layer 390 is disposed in the display area DA, and any portion of the encapsulation 390 that is disposed in the peripheral area PA may ultimately be removed. The gate pad portion GP and the data pad portion DP may not be covered by the encapsulation layer 390, and upper surfaces of the gate pad portion GP and the data pad portion DP may be exposed. After forming the encapsulation layer 390 on the display area DA and peripheral area PA, a portion of the encapsulation layer 390 disposed on the peripheral area PA may be removed. In this case, a laser may be used. The laser may irradiate a boundary between the display area DA and the peripheral area PA of the substrate 110. As a result, a lateral portion of the encapsulation layer 390 may include a thermal distortion portion. The thermal distortion portion means a trace of laser irradiation. An angle between the lateral surface of the encapsulation layer and the substrate is equal to or greater than about 80°.

A barrier layer 392 is disposed on the encapsulation layer 390. The barrier layer 392 may cover an upper surface and the lateral surface of the encapsulation layer 390.

The barrier layer 392 may be made of an inorganic material. For example, the barrier layer 392 may be made of a silicon nitride (SiNx). The barrier layer 392 is formed to cover the upper surface and the lateral surface of the encapsulation layer 390. Thus, oxygen and moisture may be prevented from permeating through the encapsulation layer 390. If the barrier layer 392 were to cover only the upper surface of the encapsulation layer 390, oxygen or moisture would be able to permeate through the lateral surface of the encapsulation layer. If oxygen or moisture passed through the encapsulation layer 390, reliability of an element such as the thin film transistor could be compromised. In the exemplary embodiment, reliability of the element may be improved by forming the barrier layer 392 to cover the upper surface and the lateral surface of the encapsulation layer 390 by using a material preventing permeation of oxygen and moisture.

Furthermore, the barrier layer 392 may cover portions of lateral surfaces of the third insulating layer 370, the roof layer 360, the second insulating layer 350, the first insulating layer 240, and the light blocking member 220 disposed under an edge portion of the encapsulation layer 390. Even furthermore, the barrier layer 392 may cover a portion of the upper surface of the passivation layer 180 adjacent to the edge portion of the encapsulation layer 390 and not covered by the encapsulation layer 390. Thus, the edge portion of the barrier layer 392 may be disposed outside of the edge portion of the encapsulation layer 390. For example, the edge portion of the encapsulation layer 390 may be disposed on the display area DA of the substrate 110, with the edge portion of the barrier layer disposed on a boundary between the display area DA and the peripheral area PA of the substrate 110. Alternatively, the edge portion of the barrier layer 392 may be disposed on the peripheral area PA of the substrate 110.

The barrier layer 392 may be disposed on the display area DA, and may not be disposed on the peripheral area PA. The gate pad portion GP and the data pad portion DP may not be covered by the encapsulation layer 390, and the gate pad portion GP and the data pad portion DP may be exposed to the outside. After forming the barrier layer 392 on the display area DA and peripheral area PA, a portion of the barrier layer 392 disposed on the peripheral area PA may be removed. In this case, a laser may be used to remove the portion of the barrier layer. The laser may irradiate a boundary between the display area DA and the peripheral area PA. As a result, a lateral portion of the encapsulation layer 390 may include a thermal distortion portion. The thermal distortion portion may be disposed on the boundary between the display area DA and the peripheral area PA. However, the exemplary embodiment is not limited thereto, and the thermal distortion portion of the barrier layer 392 may be disposed on a portion of the peripheral area PA adjacent to the boundary between the display area DA and the peripheral area PA.

Although not illustrated, a polarizer may be further formed at top and bottom surfaces of the display device. The polarizer may consist of a first polarizer and a second polarizer. The first polarizer may be attached to a bottom surface of the substrate 110, and the second polarizer may be attached to the encapsulation layer 390.

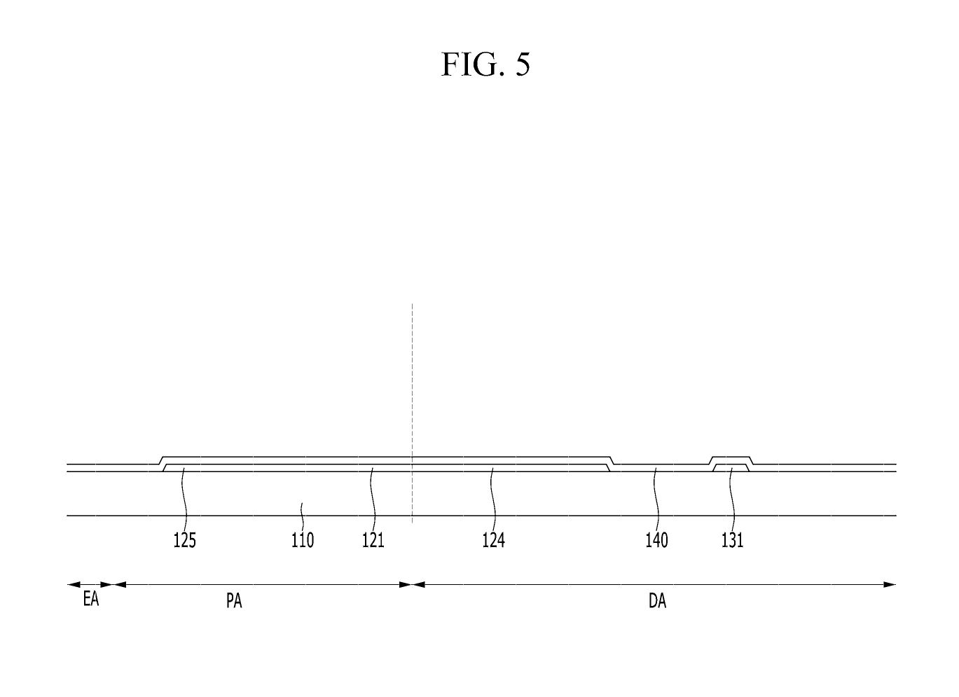

Next, with reference to FIG. 5 to FIG. 22, a manufacturing method of a display device according to an exemplary embodiment will be described as follows. In addition, the description will be made with reference to FIG. 1 to FIG. 4.

FIGS. 5 to 22 are process cross-sectional views of a manufacturing method of a display device according to an exemplary embodiment.

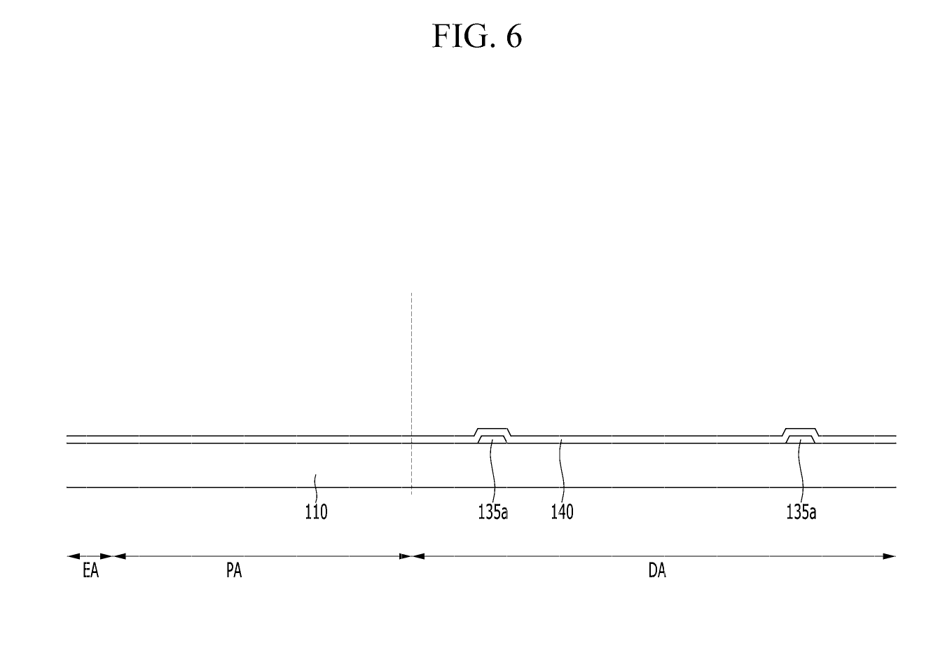

As shown in FIG. 5 and FIG. 6, a gate line 121 extending in a first direction and a gate electrode 124 protruding from the gate line 121 are formed on a substrate 110 made of glass or plastic. The gate line 121 may substantially extend in a horizontal direction.

In forming the gate line 121 and gate electrode 124, a gate pad 125 connected to the gate line 121 is formed together therewith. The gate line 121 is extended from a display area DA to a peripheral area PA. The gate pad 125 extends from an end portion of the gate line 121, and is disposed in the peripheral area PA. The gate pad 125 may be made of the same material as the gate line 121 and the gate electrode 124, and may be disposed on the same layer.

In addition, a reference voltage line 131 and storage electrodes 135a and 135b protruding from the reference voltage line 131 may be formed together such that they are separated from the gate line 121. The reference voltage line 131 extends in a direction parallel to the gate line 121. The storage electrodes 135a and 135b include a pair of first storage electrodes 135a extending substantially perpendicular to the reference voltage line 131, and a second storage electrode 135b connecting the pair of first storage electrodes 135a. The reference voltage line 131 and the storage electrodes 135a and 135b may surround the pixel electrode 191 to be described below.

Next, using an inorganic insulating material such as a silicon nitride (SiNx) or a silicon oxide (SiOx), a gate insulating layer 140 is formed on the gate line 121, the gate electrode 124, the gate pad 125, the reference voltage line 131, and the storage electrodes 135a and 135b. The gate insulating layer 140 may consist of a single layer or multiple layers.

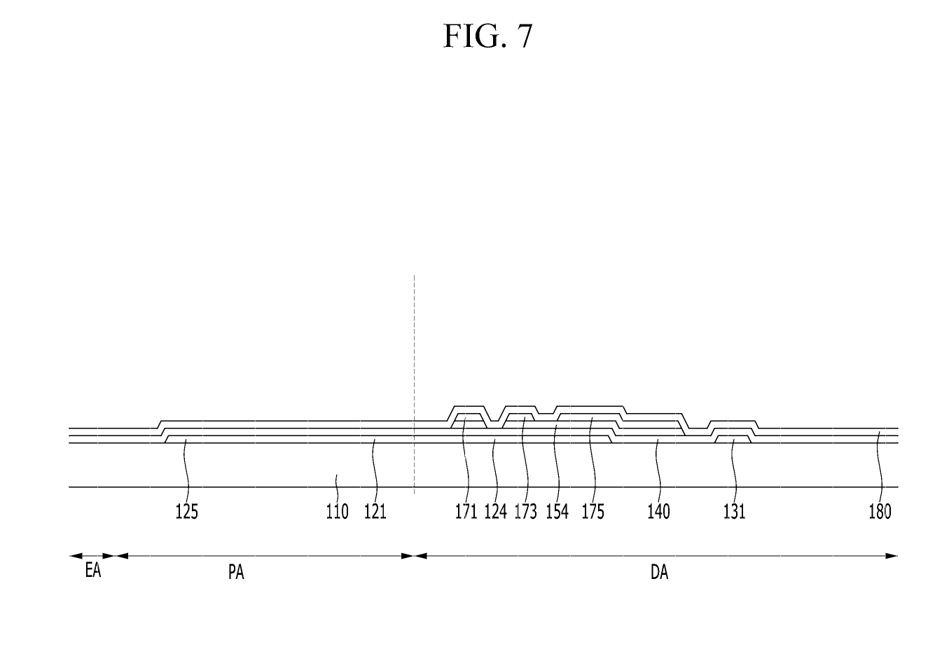

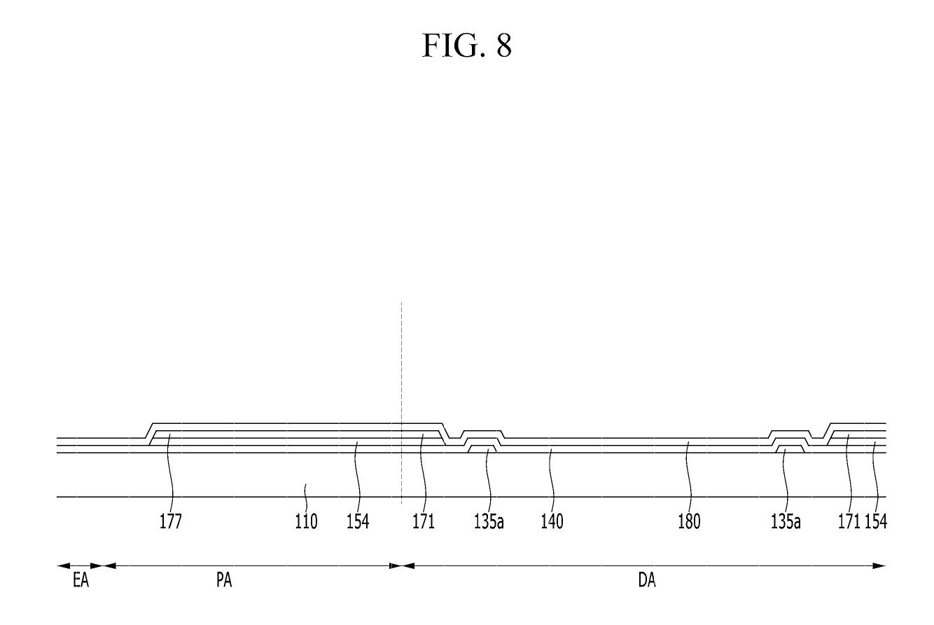

As shown in FIG. 7 and FIG. 8, a semiconductor material such as amorphous silicon, polycrystalline silicon, or a metal oxide is deposited on the gate insulating layer 140. Next, after depositing a metal material, the metal material and the semiconductor material are patterned to form a semiconductor 154, a data line 171, a source electrode 173, a drain electrode 175, and a data pad 177. The data line 171, the source electrode 173, the drain electrode 175, and the data pad 177 may consist of a single layer or multiple layers.

The semiconductor 154 is positioned on the gate electrode 124, and is also disposed under the data line. In the above description, the method in which the semiconductor material and the metal material are sequentially deposited and are then simultaneously patterned is described, but the exemplary embodiment is not limited thereto. The semiconductor 154 is formed first by depositing and then patterning the semiconductor material, and then the metal material may be deposited and patterned to form the data line 171. In this case, the semiconductor 154 may not be disposed under the data line 171.

The data line 171 extends in a second direction to cross the gate line 121 and the reference voltage line 131. The data line 171 may extend in a substantially vertical direction. The source electrode 173 protrudes above the gate electrode 124 from the data line 171, and a part of the drain electrode 175 is surrounded by the source electrode 173. The data line 171, the source electrode 173, and the drain electrode 175 are disposed in the display area DA, and the data line 171 extends to the peripheral area PA.

The data pad 177 is connected to the data line 171. The data pad 177 extends from an end portion of the data line 171. The end portion of the data line 171 is positioned in the peripheral area PA, and the data pad 177 is positioned in the peripheral area PA. The data pad 177 may be made of the same material as and disposed on the same layer as the data line 171, the source electrode 173, and the drain electrode 175.

The gate electrode 124, the source electrode 173, and the drain electrode 175 form one thin film transistor (TFT) Q along with the semiconductor 154. The thin film transistor Q may function as a switching element that transmits a data voltage of the data line 171. In this case, a channel of the switching element is formed in the semiconductor 154 between the source electrode 173 and the drain electrode 175.

Next, a passivation layer 180 is formed on the data line 171, the source electrode 173, the drain electrode 175, and an exposed portion of the semiconductor 154. The passivation layer 180 may be made of an organic insulating material or an inorganic insulating material, and may consist of a single layer or multiple layers.

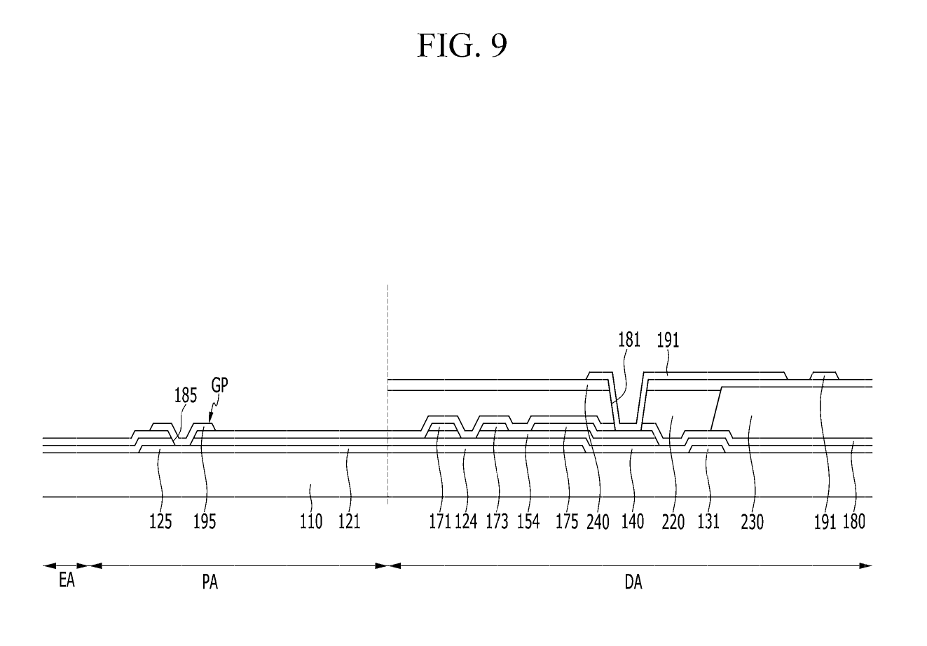

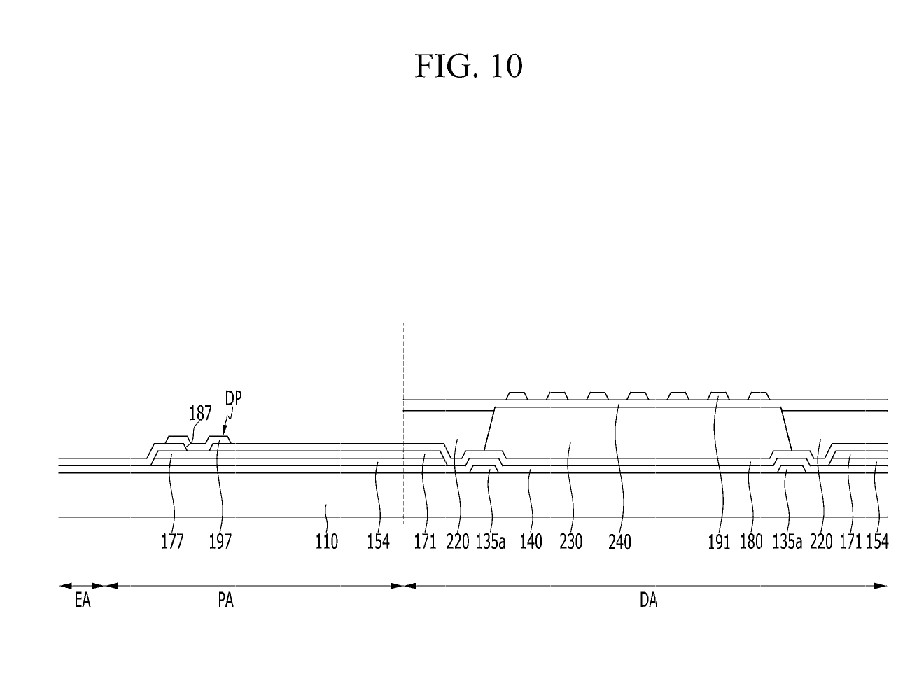

As shown in FIGS. 9 and 10, a color filter 230 is formed on the passivation layer 180. The color filter 230 may be formed inside each pixel, and may not be formed at an edge of the pixel. A plurality of color filters 230 allowing different wavelengths of light to be transmitted therethrough may be formed, and in this case, color filters 230 of the same color may be formed along a column direction. When forming color filters 230 of three colors, a color filter 230 of a first color may be formed first using a mask, the mask may be shifted to form a color filter 230 of a second color, and the mask may be shifted again to form a color filter 230 of a third color.

Subsequently, a light blocking member 220 is formed on the passivation layer 180 by using a light blocking material. The light blocking member 220 may be disposed at the edge of the pixel, and may overlap the gate line 121, the data line 171, and the thin film transistor Q to prevent light leakage. However, the exemplary embodiment is not limited thereto, and the light blocking member 220 may overlap the gate line 121 and the thin film transistor Q, but not the data line 171.

Next, a first insulating layer 240 is formed on the color filter 230 and the light blocking member 220. The first insulating layer 240 may be formed of an organic insulating material, and may serve to planarize upper surfaces of the color filter 230 and the light blocking member 220. The first insulating layer 240 may be formed as a dual layer by sequentially depositing a layer made of an organic insulating material and a layer made of an inorganic insulating material.

Next, the first insulating layer 240, the light blocking member 220, and the passivation layer 180 are patterned to form a first contact hole 181 that exposes at least some of the drain electrode 175. In the step of the forming of the first contact hole 181, a second contact hole 185 exposing at least some of the gate pad 125 and a third contact hole 187 exposing at least some of the data pad 177 may be formed together therewith.

Next, a transparent metal material such as an indium tin oxide (ITO) or an indium zinc oxide (IZO) is deposited on the first insulating layer 240 and then patterned to form the pixel electrode 191. The pixel electrode 191 is connected to the drain electrode 175 through the first contact hole 181. The pixel electrode 191, which has an overall quadrangular shape, includes horizontal and vertical stem portions 193 and 192 crossing each other, and a minute branch portion 194 extending from the horizontal and vertical stem portions 193 and 192.

In the step of the forming of the pixel electrode 191, a gate contact assistant 195 and a data contact assistant 197 are formed together therewith. The gate contact assistant 195 is connected to the gate pad 125 through the second contact hole 185, and the data contact assistant 197 is connected to the data pad 177 through the third contact hole 187. The gate contact assistant 195, the data contact assistant 197, and the pixel electrode 191 may be made of the same material, and disposed as the same layer.

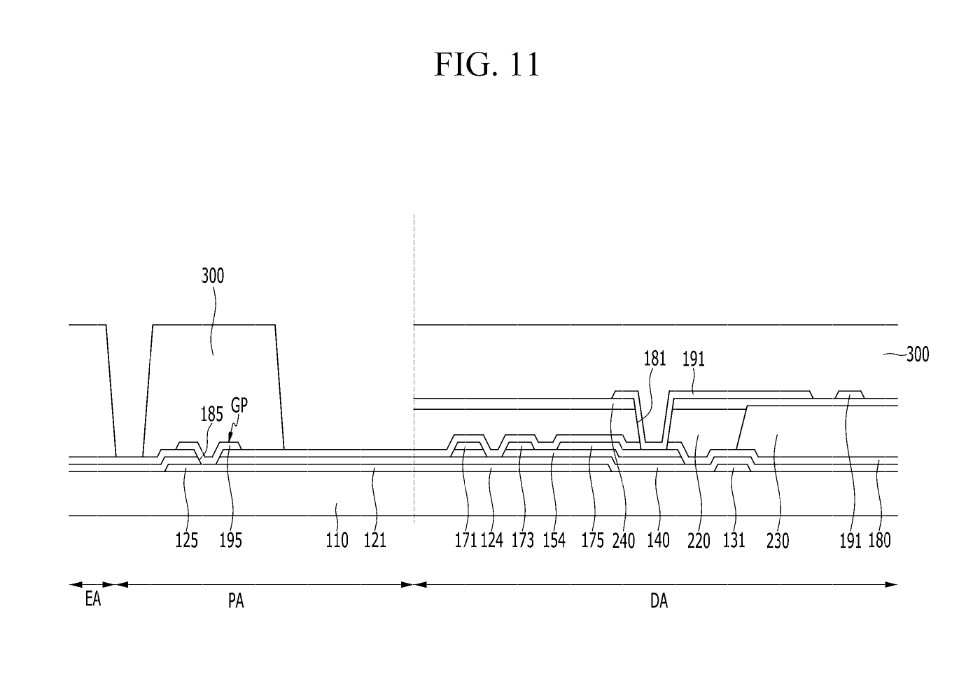

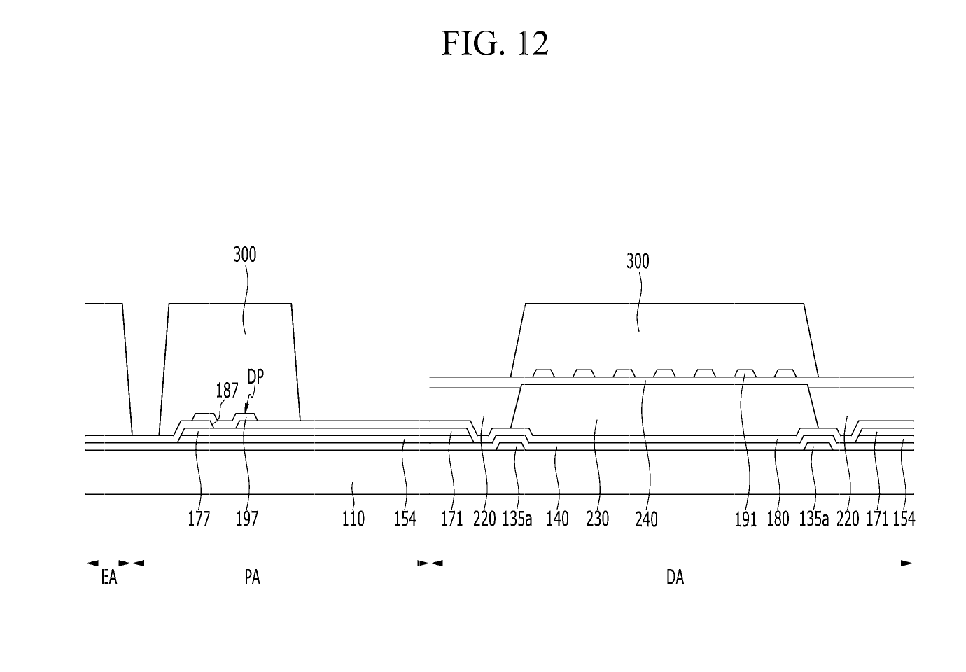

As shown in FIGS. 11 and 12, a sacrificial layer 300 is formed on the pixel electrode 191, the gate contact assistant 195, the data contact assistant 197, and the first insulating layer 240. In a plan view, the sacrificial layer 300 may be formed to extend in the column direction. The sacrificial layer 300 may be formed in the display area DA and the peripheral area PA. In the display area DA, the sacrificial layer 300 may overlap the pixel electrode 191, but not the data line 171. In the peripheral area PA, the sacrificial layer 300 may overlap the gate contact assistant 195 and the data contact assistant 197.

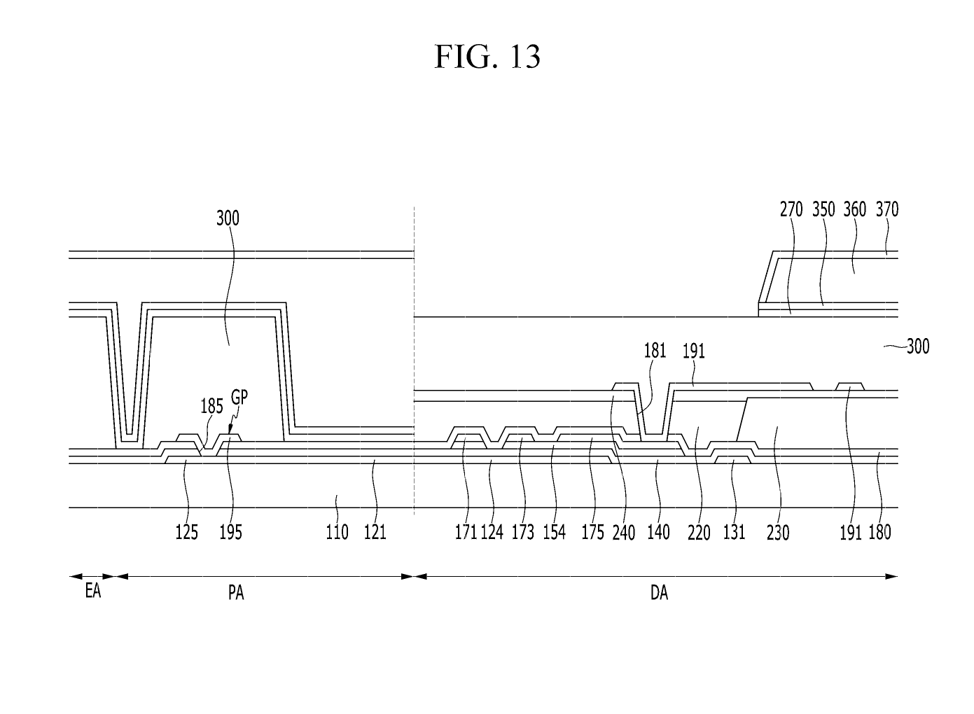

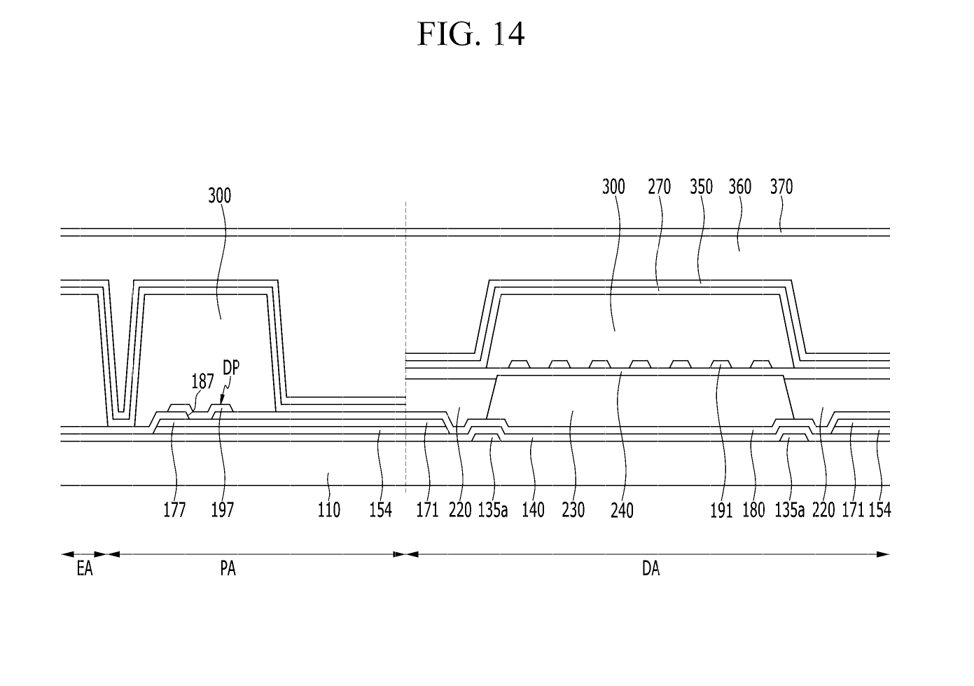

As shown in FIGS. 13 and 14, a transparent metal material such as an indium tin oxide (ITO) or an indium zinc oxide (IZO) is deposited on the sacrificial layer 300 to form a common electrode 270.

Next, a second insulating layer 350 may be formed on the common electrode 270 by using an inorganic insulating material such as a silicon oxide or a silicon nitride.

Subsequently, an organic material is coated on the second insulating layer 350 and is then patterned to form a roof layer 360. In this case, the patterning may be performed such that a portion of an organic material overlapping the gate line 121 and the thin film transistor Q is removed. Accordingly, the roof layer 360 may extend along a row direction.

After the roof layer 360 is patterned, a curing process is performed on the roof layer 360 by irradiating the roof layer 360 with light. Since the roof layer 360 is hardened after performing the curing process, the roof layer 360 may maintain its shape even if a predetermined space is created under the roof layer 360.

Portions of the second insulating layer 350 and the common electrode 270 overlapping the gate line 121 and the thin film transistor Q are then removed by patterning the second insulating layer 350 and the common electrode 270 by using the roof layer 360 as a mask.

Next, an inorganic insulating material such as a silicon nitride (SiNx) or a silicon oxide (SiOx) may be deposited on the roof layer 360 and then patterned to form a third insulating layer 370. In this case, the patterning may be performed such that portions of the inorganic insulating material overlapping the gate line 121 and the thin film transistor Q are removed. The third insulating layer 370 may cover an upper surface of the roof layer 360, and may further cover a lateral surface of the roof layer 360.

As the roof layer 360, the second insulating layer 350, the common electrode 270, and the third insulating layer 370 are patterned, some of the sacrificial layer 300 is exposed to the outside.

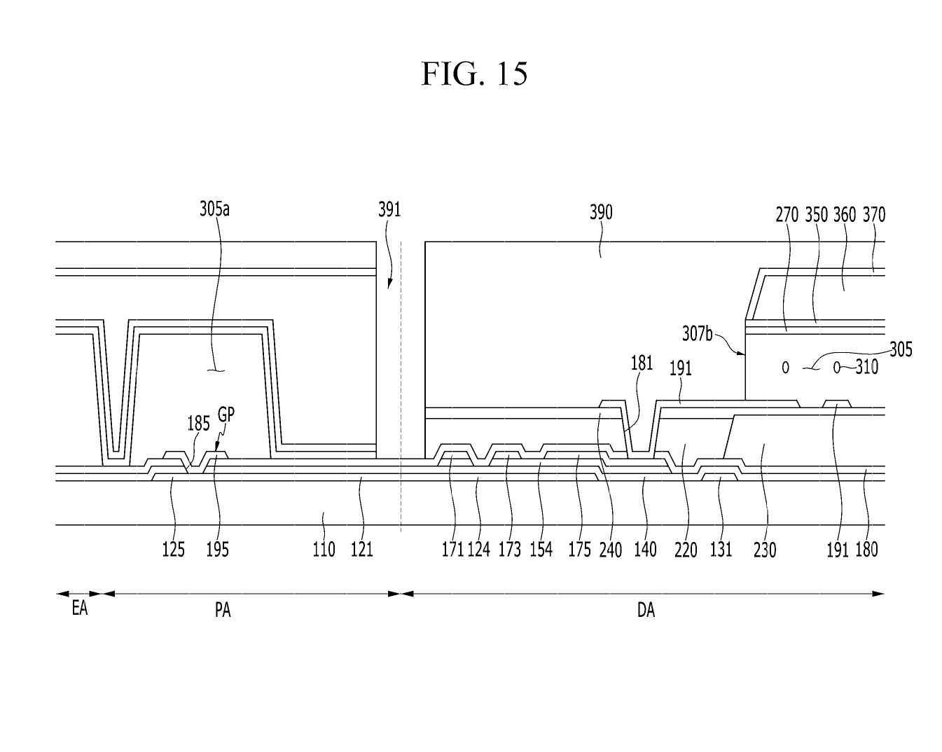

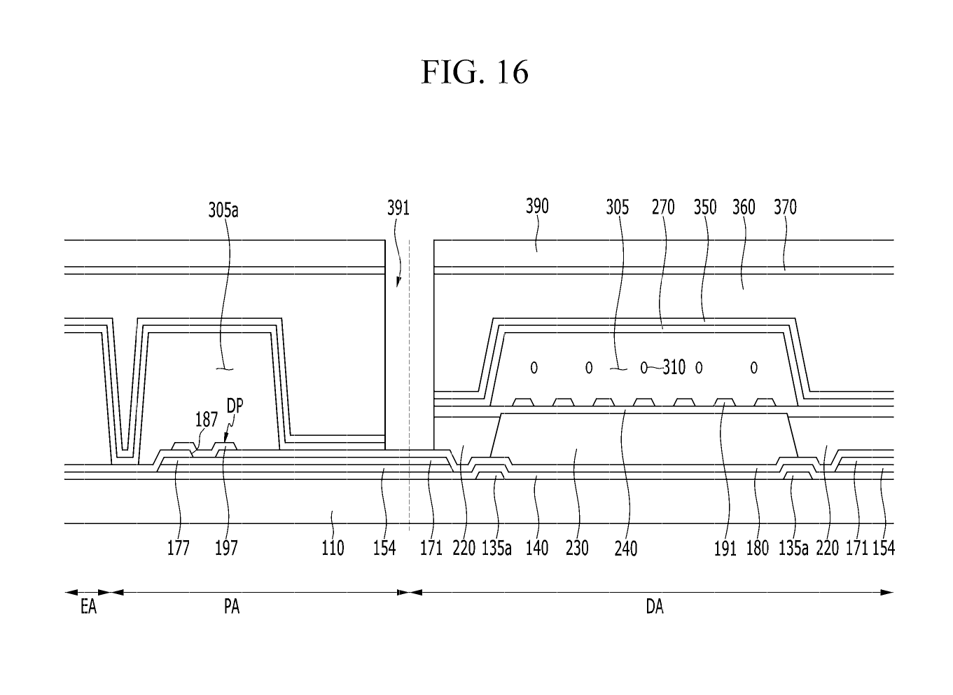

When a developer or a stripper solution is supplied on the sacrificial layer 300 to completely remove the sacrificial layer 300, or when an ashing process is used to completely remove the sacrificial layer 300, a microcavity 305 and a dummy microcavity 305a, as shown in FIGS. 15 and 16, are created at the position where the sacrificial layer 300 was previously positioned. The microcavity 305 is disposed in the display area DA, while the dummy microcavity 305a is disposed in the peripheral area PA.

The pixel electrode 191 and the roof layer 360 are spaced apart from each other while interposing the microcavity 305 therebetween. The gate contact assistant 195 and the roof layer 360 are spaced apart from each other while interposing the microcavity 305 therebetween. The data contact assistant 197 and the roof layer 360 are spaced apart from each other while interposing the microcavity 305 therebetween. The roof layer 360 covers an upper surface of the microcavity 305 and some of a lateral surface thereof, and covers an upper surface of the dummy microcavity 305a and a portion of a lateral surface thereof.

The microcavity 305 is exposed to the outside through portions where the roof layer 360 and the common electrode 270 are removed, and the portions via which the microcavity 305 is exposed may be called injection holes 307a and 307b. The two injection holes 307a and 307b may be formed in one microcavity 305. For example, a first injection hole 307a exposing a lateral surface of a first edge of the microcavity 305 and a second injection hole 307b exposing a lateral surface of a second edge of the microcavity 305 may be formed. The first edge and the second edge may face each other. For example, the first edge may be an upper edge of the microcavity 305, while the second edge may be a lower edge of the microcavity 305.

Next, when an aligning agent containing an alignment material is dripped onto the substrate 110 using a spin coating method or an inkjet method, the aligning agent is injected into the microcavity 305 via the injection holes 307a and 307b. When a curing process is performed after the aligning agent is injected into the microcavity 305, a solution component is evaporated and the alignment material remains at inner wall surfaces of the microcavity 305.

Accordingly, a first alignment layer 11 may be formed on the pixel electrode 191, and a second alignment layer 21 may be formed under the common electrode 270. The first and second alignment layers 11 and 21 are formed to face each other while interposing the microcavity 305 therebetween, and to be connected to each other at a lateral wall of the edge of the microcavity 305.

In this case, the first and second alignment layers 11 and 21 may be aligned in a direction perpendicular to the substrate 110, except at the lateral surface of the microcavity 305.

Next, when an inkjet method or dispensing method is used to drip a liquid crystal material onto the substrate 110, the liquid crystal material is injected through the injection holes 307a and 307b into the microcavity 305 by a capillary force. Accordingly, a liquid crystal layer consisting of liquid crystal molecules 310 is formed inside the microcavity 305.

The alignment layers 11 and 21 and the LC layer may be formed or may not be formed in the dummy microcavity 305a.

Next, a material that does not react with the LC molecules 310 is deposited on the third insulating layer 370 to form an encapsulation layer 390. The encapsulation layer 390 is formed such that it covers the injection holes 307a and 307b to seal the microcavity 305, thereby preventing the LC molecules 310 formed inside the microcavity 305 from being leaked to the outside. The encapsulation layer 390 may be made of an organic insulating material.

Next, a portion of the encapsulation layer 390 disposed on a boundary between the display area DA and the peripheral area PA of the substrate 110 is removed to form a trench 391.

To form the trench 391, a laser may irradiate a portion of the encapsulation layer 390 disposed on a boundary between the display area DA and the peripheral area PA of the substrate 110. A lateral portion of the encapsulation layer 390 may include a thermal distortion portion formed by irradiation by the laser. However, the exemplary embodiment is not limited thereto, and the trench 391 may be formed on the encapsulation layer 390 by using a photolithography process.

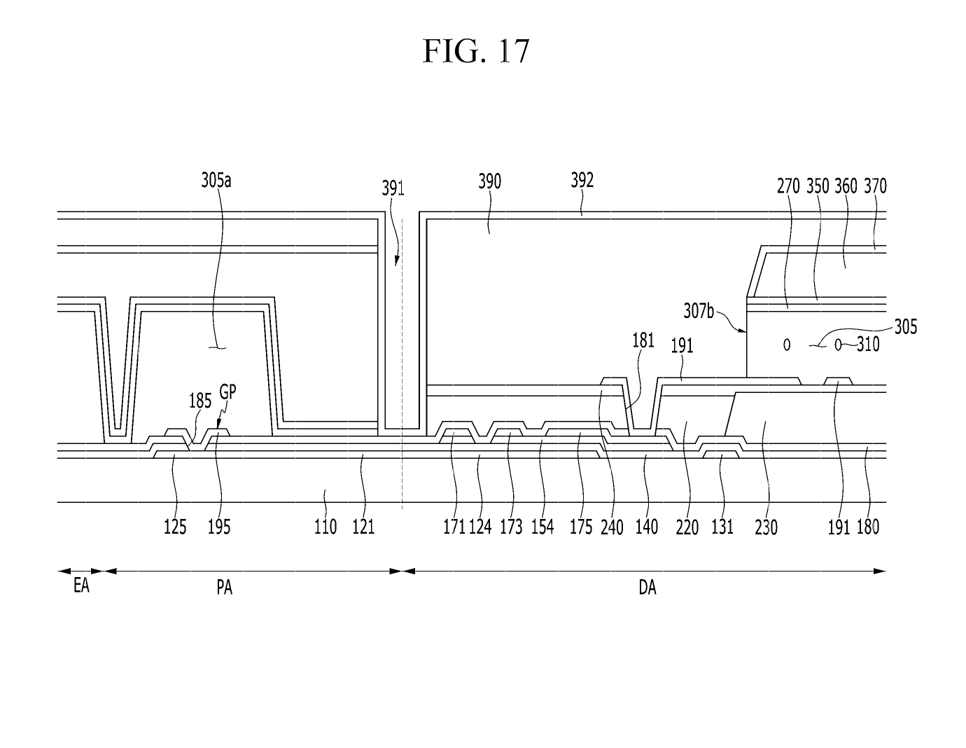

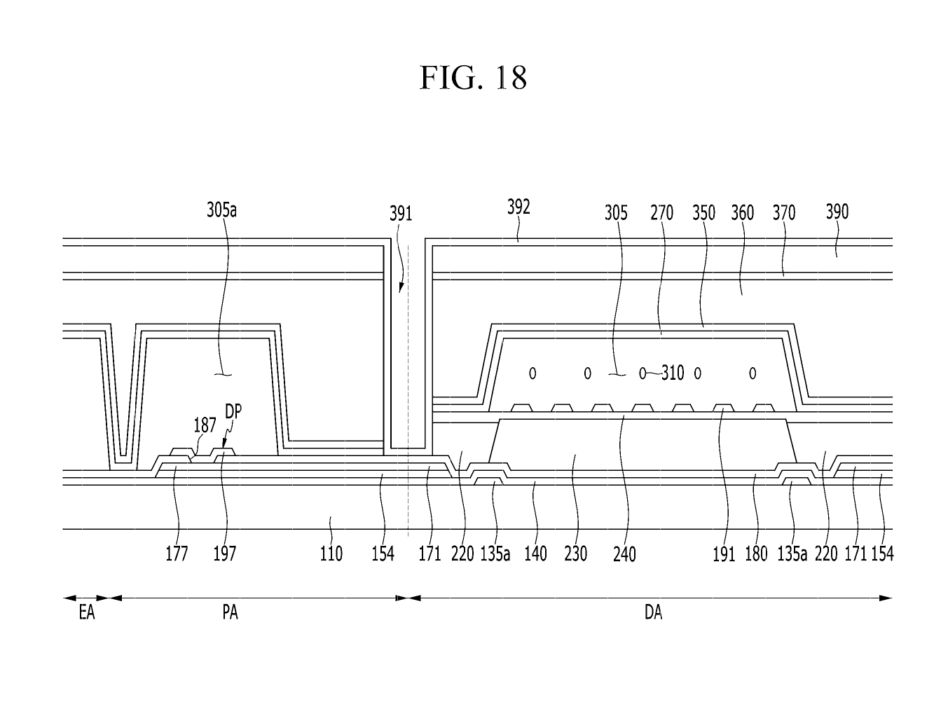

As shown in FIG. 17 and FIG. 18, an inorganic material is deposited on the encapsulation layer 390 to form a barrier layer 392. The barrier layer 392 is also formed in the trench 391. Thus, the barrier layer 392 covers an upper surface and a lateral surface of the encapsulation layer 390, and a portion of the passivation layer 180 disposed in the trench 391.

The barrier layer 392 may be made of a silicon nitride (SiNx). The barrier layer 392 may be made of another material preventing permeation of oxygen and moisture instead of the silicon nitride (SiNx).

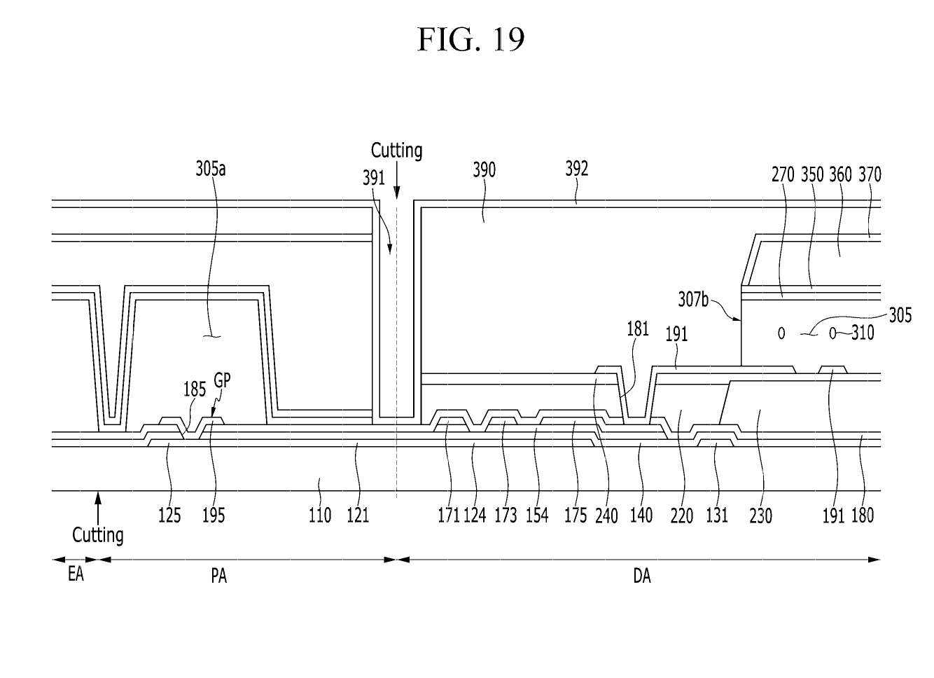

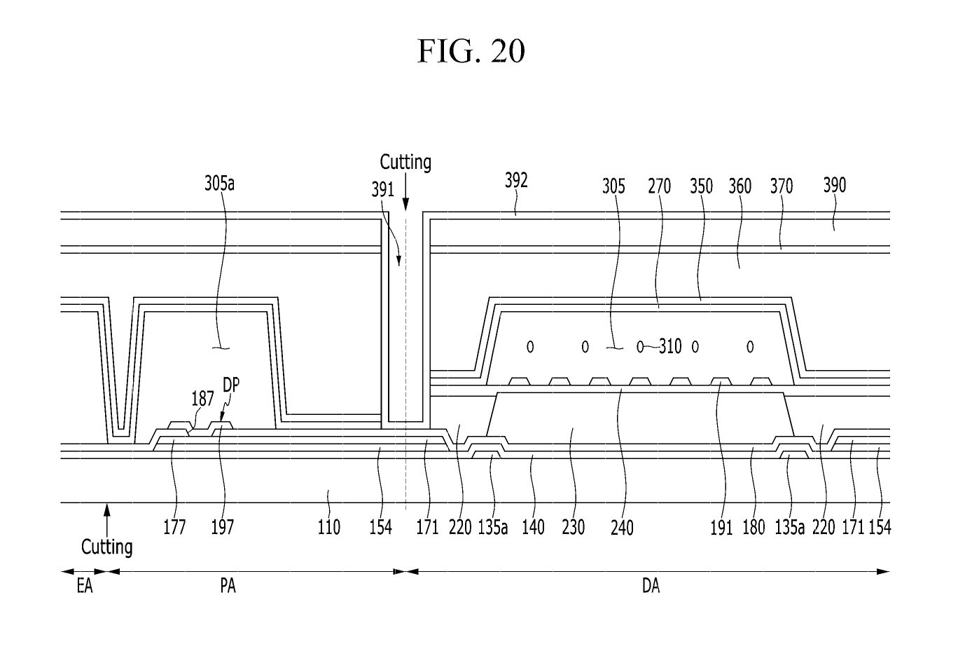

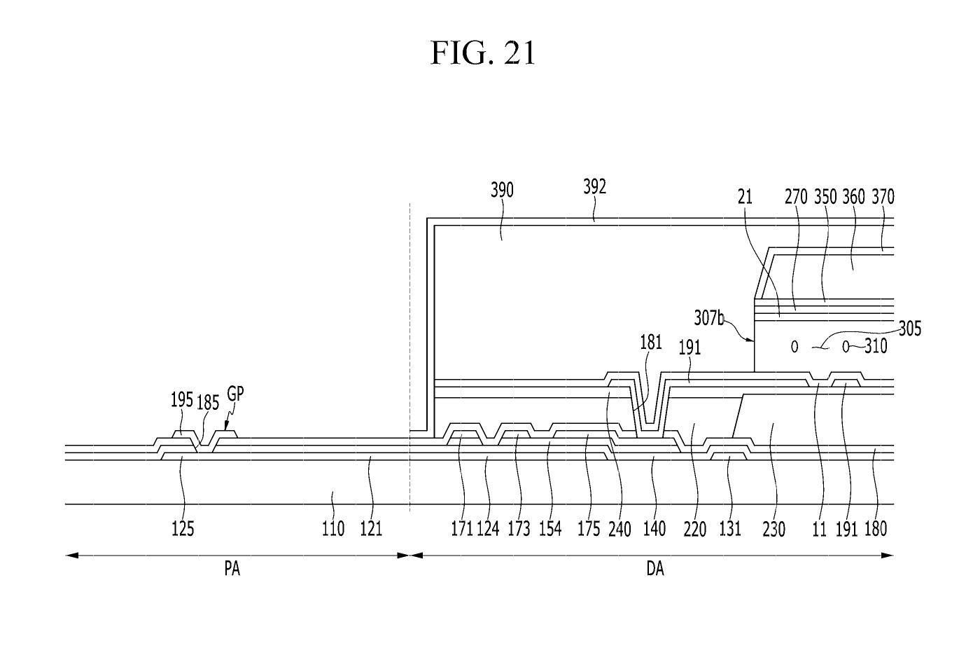

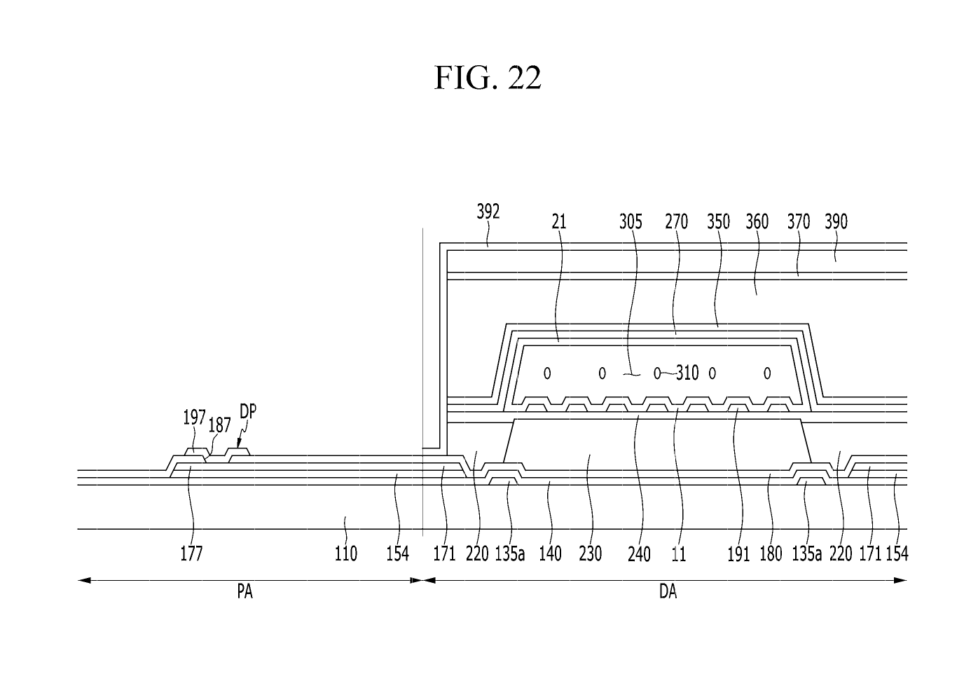

As shown in FIG. 19 and FIG. 20, a portion of the barrier layer 392 disposed in the trench 391 is cut, and a boundary between the peripheral area PA and an extra area EA of the substrate 110 is cut. After cutting the portion of the barrier layer 392 and the boundary between the peripheral area PA and the extra area EA of the substrate 110, the extra area EA of the substrate 110 is separated from the peripheral area PA of the substrate. As a result, a portion of the barrier layer 392 disposed on the peripheral area PA and the extra area EA of the substrate 110 is separated with the extra area EA of the substrate 110. That is, a portion of the barrier layer 392 disposed on the peripheral area PA and the extra area EA of the substrate 110 is removed with the extra area EA of the substrate 110. As shown in FIG. 21 and FIG. 22, the display area DA and the peripheral area PA of the substrate 110 remain. The barrier layer 392 remains only on the display area DA of the substrate 110. Portions of the encapsulation layer 390, the third insulating layer 370, the roof layer 360, the second insulating layer 350, and the common electrode 270 disposed on the peripheral area PA and the extra area EA of the substrate 110 may be removed together.

In the step of cutting the barrier layer 392, a laser may irradiate a portion of the barrier layer 392 disposed in the trench 391. A location to be irradiated may be a portion of the barrier layer 392 disposed on a boundary between the display area DA and the peripheral area PA of the substrate 110. However, the exemplary embodiment is not limited thereto. The location to be irradiated may be a portion of the barrier layer 392 disposed on a portion of the peripheral area PA adjacent to the boundary between the display area DA and the peripheral area PA of the substrate 110.

A lateral portion of the barrier layer 392 may include a thermal distortion portion formed by irradiation of the laser. An irradiated location does not overlap the gate pad portion GP and the data pad portion DP. Thus, damage to the gate contact assistants 195 and the data contact assistants 197 may be prevented.

However, the exemplary embodiment is not limited thereto, and the barrier layer 392 may be cut by using a mechanical method. The barrier layer may be cut without damage to portions of elements including the substrate 110 disposed under the barrier layer 392 by using a half-cutting method.

It is illustrated that a cutting region of the barrier layer 392 overlaps the trench 391, but the exemplary embodiment is not limited thereto. Alternatively, the cutting region of the barrier layer 392 may not overlap the trench 391. The cutting region of the barrier layer 392 may be on the peripheral area PA of the substrate 110. A portion overlapping the barrier layer 392, the encapsulation layer 390, and the roof layer 360 may be cut. Furthermore, a portion overlapping the barrier layer 392, the encapsulation layer 390, and the dummy microcavity 305a may be cut.

In the cutting of the substrate 110, a mechanical cutting method may be used.

Subsequently, although not illustrated, polarizers may be further attached to top and bottom surfaces of the display device. The polarizers may include a first polarizer and a second polarizer. The first polarizer may be attached to the bottom surface of the substrate 110, and the second polarizer may be attached to the barrier layer 392.

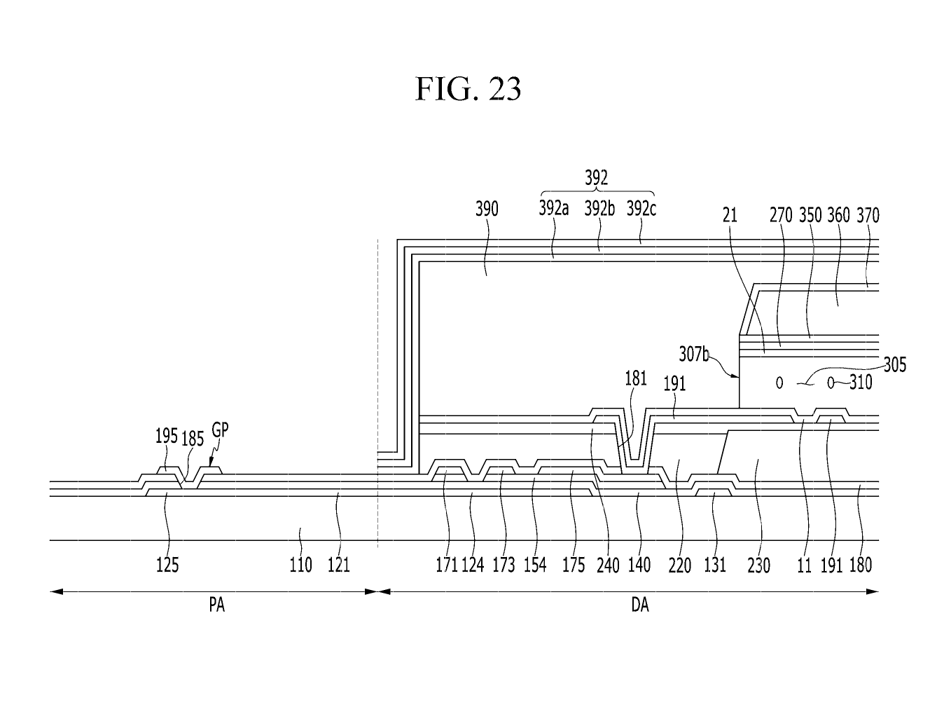

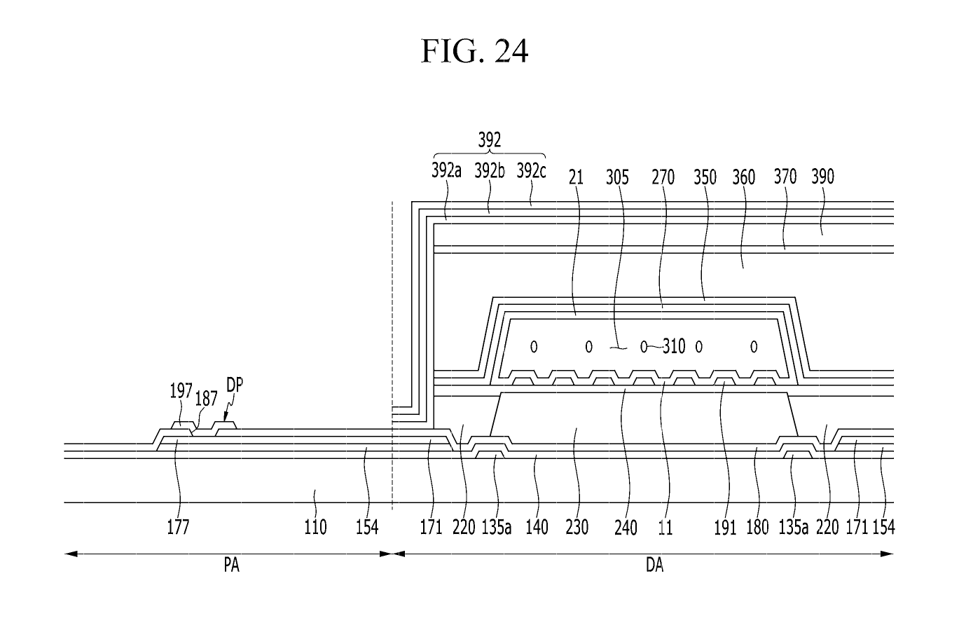

Next, referring to FIG. 23 to FIG. 24, a display device according to an exemplary embodiment will be described as follows.

Since the display device according to the current exemplary embodiment illustrated in FIG. 23 and FIG. 24 has substantially the same configuration as the display device according to the exemplary embodiment illustrated in FIGS. 1 to 4, a description thereof will be omitted. The current exemplary embodiment differs from the aforementioned exemplary embodiment in that the barrier layer consists of multiple layers, and will be described below in detail.

FIG. 23 and FIG. 24 are cross-sectional view of a display device according to an exemplary embodiment of the present invention.

Referring to FIG. 23 and FIG. 24, a barrier layer 392 is disposed on the encapsulation layer 390. The barrier layer 392 may cover an upper surface and a lateral surface of the encapsulation layer 390. In the aforementioned exemplary embodiment, the barrier layer 392 consists of a single layer. In the current exemplary embodiment, however, the barrier layer 392 consists of multiple layers.

The barrier layer 392 includes a first barrier layer 392a and a second barrier layer 392b disposed on the first barrier layer 392a. The first barrier layer 392a may be made of an inorganic material, and the second barrier layer 392b may be made of an organic material.

The barrier layer 392 further includes a third barrier layer 392c disposed on the second barrier layer 392b. The third barrier layer 392c may be made of an inorganic material.

In the current exemplary embodiment, it is illustrated that the barrier layer 392 consists of three layers. However, the exemplary embodiment is not limited thereto. Alternatively, the barrier layer 392 may consist of two or more layers, including four layers.

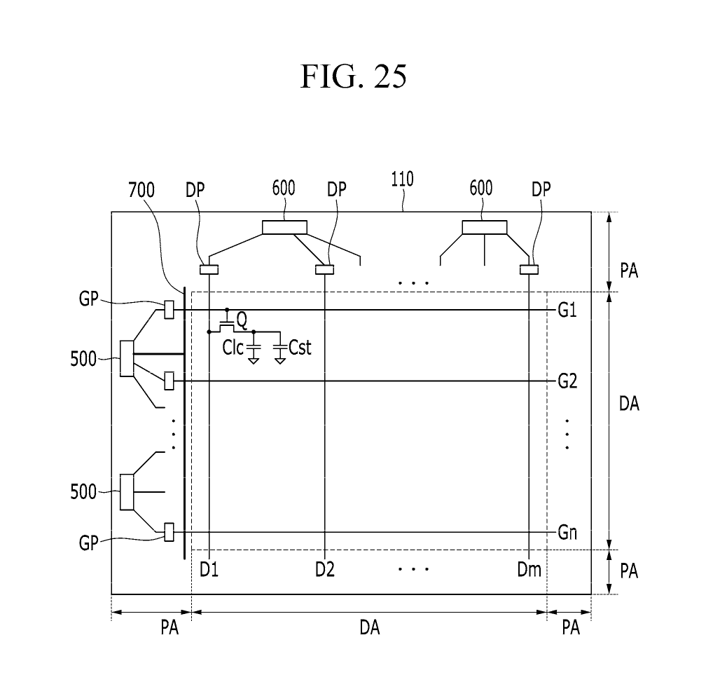

Next, referring to FIG. 25 to FIG. 27, a display device according to an exemplary embodiment will be described as follows.

Since the display device according to the current exemplary embodiment illustrated in FIG. 25 to FIG. 27 has substantially the same configuration as the display device according to the exemplary embodiment illustrated in FIGS. 1 to 4, a description thereof will be omitted. The current exemplary embodiment differs from the aforementioned exemplary embodiment in that a ground pattern is further disposed under the barrier layer, and will be described below in detail.

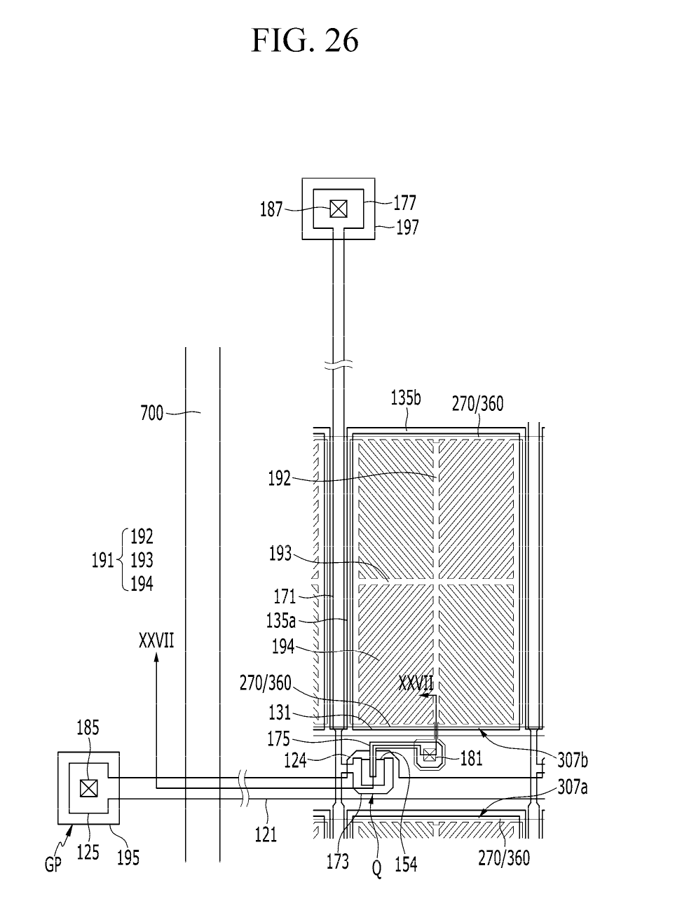

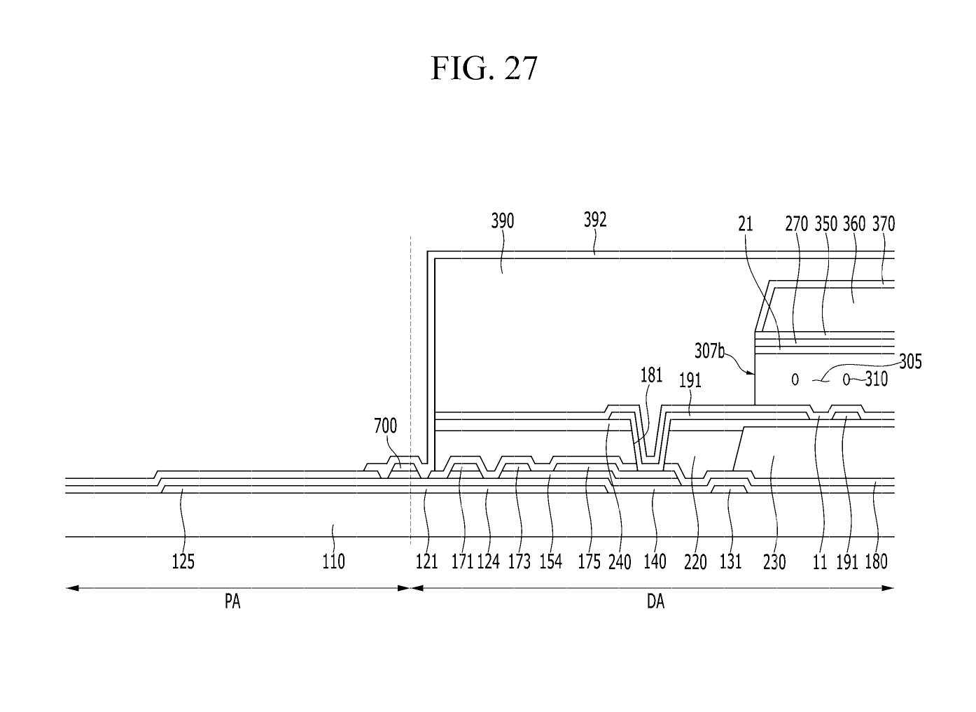

FIG. 25 is a plan view of a display device according to an exemplary embodiment, FIG. 26 is a partial plan view of a display device according to an exemplary embodiment, and FIG. 27 is a cross-sectional view of a display device according to an exemplary embodiment taken along the line XXVII-XXVII of FIG. 26.

Referring to FIG. 25 to FIG. 27, a display device according to the exemplary embodiment further includes a ground pattern 700 disposed on the substrate 110. The ground pattern 700 may be made of the same material as the data line 171, and the ground pattern 700 and the data line 171 may be disposed as the same layer. However, the exemplary embodiment is not limited thereto. The ground pattern 700 may be made of the same material as the gate line 121, and the ground pattern 700 and the gate line 121 may be disposed as the same layer.

The ground pattern 700 may be connected to the gate driver 500, and a ground voltage may be applied to the ground pattern 700. However, the exemplary embodiment is not limited thereto. That is, the ground pattern 700 may be connected to the data driver 600.

The ground pattern 700 may be disposed on the peripheral area PA or the boundary between the display area DA and the peripheral area PA. The ground pattern 700 may have a rod shape extending in a direction parallel to the data line 171. However, the exemplary embodiment is not limited thereto. The ground pattern 700 may have a rod shape extending in a direction parallel to the gate line 121.

The ground pattern 700 is connected to the barrier layer 392. The barrier layer 392 may cover the ground pattern 700. The barrier layer 392 may be made of an inorganic material. Particularly, the barrier layer 392 may be made of a transparent conductive material. The barrier layer 392 may be made of a transparent metal or a metal oxide. For example, the barrier layer 392 may be made of a material such as an indium zinc oxide (IZO), an amorphous indium tin oxide (a-ITO), etc.

The barrier layer 392 may be made of a conductive inorganic material and be connected to the ground pattern 700, and static electricity may therefore be dispersed when static electricity occurs. Simultaneously, the barrier layer 392 may prevent oxygen and moisture from permeating through the encapsulation layer from the outside.

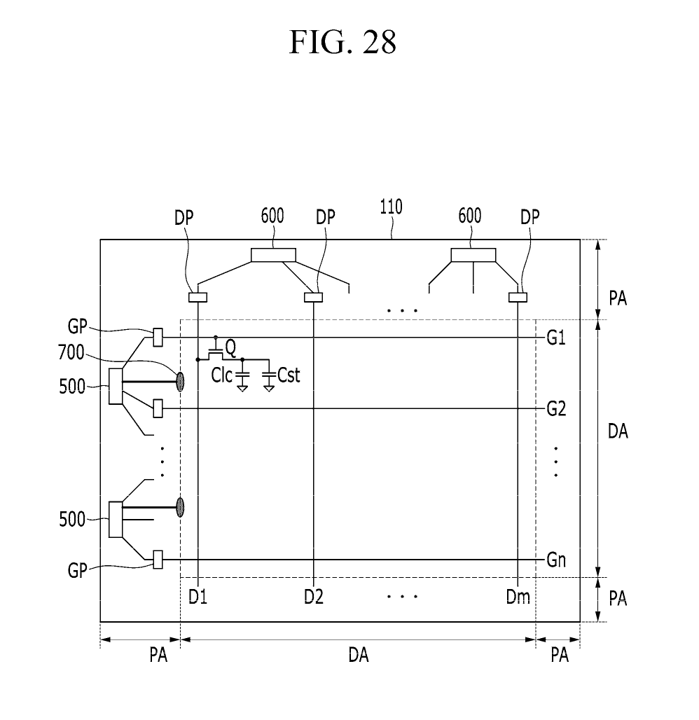

Next, referring to FIG. 28, a display device according to an exemplary embodiment will be described as follows.

Since the display device according to the current exemplary embodiment illustrated in FIG. 28 has substantially the same configuration as the display device according to the exemplary embodiment illustrated in FIG. 25 to FIG. 27, a description thereof will be omitted. The current exemplary embodiment differs from the aforementioned exemplary embodiment in a shape of the ground pattern, and will be described below in detail.

FIG. 28 is a plan view of a display device according to an exemplary embodiment.

Referring to FIG. 28, a display device according to the exemplary embodiment includes a ground pattern 700 disposed on the substrate 110. The ground pattern 700 is connected to a barrier layer 392 made of a conductive inorganic material.

In the aforementioned exemplary embodiment, the ground pattern 700 has a rod shape extending according to a predetermined direction. In the current exemplary embodiment, however, the ground pattern 700 has a dot shape. The ground pattern 700 is not limited thereto, and the ground pattern 700 may have various shapes. For example, the ground pattern 700 may have an L-shape that is curved once in a plan view.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A display device comprising:
a substrate;
a thin film transistor disposed on the substrate;
a first electrode connected to the thin film transistor;
a roof layer disposed on the first electrode and spaced apart from the first electrode by interposing a microcavity therebetween;
a liquid crystal layer positioned inside the microcavity;
an encapsulation layer positioned on the roof layer; and
a barrier layer covering an upper surface and a lateral surface of the encapsulation layer,
wherein a lateral surface of the barrier layer comprises a thermal distortion portion.

2. The display device of claim 1, wherein
the encapsulation layer comprises an organic material, and the barrier layer comprises an inorganic material.

3. The display device of claim 2, wherein
the barrier layer comprises silicon nitride.

4. The display device of claim 1, wherein the thermal distortion portion of the barrier layer is a first thermal distortion portion, and
a lateral surface of the encapsulation layer comprises a second thermal distortion portion.

5. The display device of claim 4, wherein
an angle between the lateral surface of the encapsulation layer and the substrate is equal to or greater than about 80°.

6. The display device of claim 1, wherein
the substrate comprises a display area and a peripheral area, and
the thermal distortion portion of the barrier layer is disposed on either a boundary between the display area and the peripheral area, or a portion of the peripheral area adjacent the boundary.

7. The display device of claim 1, wherein
the barrier layer comprises a first barrier layer and a second barrier layer disposed on the first barrier layer.

8. The display device of claim 7, wherein
the first barrier layer comprises an inorganic material, and the second barrier layer comprises an organic material.

9. The display device of claim 8, wherein
the barrier layer further comprises a third barrier layer disposed on the second barrier layer.

10. The display device of claim 9, wherein
the first barrier layer and the third barrier layer comprise an inorganic material, and the second barrier layer comprises an organic material.

11. The display device of claim 1, further comprising:
a ground pattern disposed on the substrate,
wherein the ground pattern is connected to the barrier layer.

12. The display device of claim 11, wherein
the barrier layer comprises a transparent conductive material.

13. The display device of claim 11, wherein
a plan shape of the ground pattern is a rod shape or dot shape.

14. The display device of claim 11, wherein
the substrate comprises a display area and a peripheral area, and
the ground pattern is disposed on the peripheral area or a boundary between the display area and the peripheral area.

15. A display device comprising:
a substrate;
a ground pattern disposed on the substrate;
a thin film transistor disposed on the substrate;
a first electrode connected to the thin film transistor;
a roof layer disposed on the first electrode and spaced apart from the first electrode by interposing a microcavity therebetween;
a liquid crystal layer positioned inside the microcavity;
an encapsulation layer positioned on the roof layer; and
a barrier layer covering an upper surface and a lateral surface of the encapsulation layer and connected to the ground pattern.

16. The display device of claim 15, wherein
the barrier layer comprises a transparent conductive material.

17. A manufacturing method of a display device comprising:
forming a thin film transistor on a display area of a substrate including the display area, a peripheral area, and an extra area;
forming a first electrode to be connected to the thin film transistor;
forming a sacrificial layer on the first electrode;
forming a roof layer on the sacrificial layer;
forming a microcavity between the first electrode and the roof layer by removing the sacrificial layer;
forming an encapsulation layer on the roof layer;
removing a portion of the encapsulation layer disposed on a boundary between the display area and the peripheral area of the substrate to form a trench;
forming a barrier layer covering an upper surface and a lateral surface of the encapsulation layer;
cutting a portion of the barrier layer disposed in the trench;
cutting the boundary between the display area and the peripheral area; and
removing a portion of the barrier layer disposed on the peripheral area and the extra area of the substrate.

18. The manufacturing method of claim 17, wherein
cutting a portion of the barrier layer disposed in the trench includes:
irradiating, with a laser, a portion of the barrier layer disposed on the boundary between the display area and the peripheral area of the substrate.

19. The manufacturing method of claim 17, wherein
removing a portion of the encapsulation layer includes
irradiating, with a laser, a portion of the encapsulation layer disposed on the boundary between the display area and the peripheral area of the substrate.

20. The manufacturing method of claim 17, wherein
the encapsulation layer comprises an organic material, and the barrier layer comprises an inorganic material.
